(19) United States
(12) Patent Application Publication
(10) Pub. No.: US 2026/0255839 A1
(43) Pub. Date: Aug. 27, 2026

(54) DISPLAY DEVICE AND ELECTRONIC APPARATUS

(71) Applicant: SONY SEMICONDUCTOR SOLUTIONS CORPORATION, KANAGAWA (JP)

(72) Inventors: KENTA HIRAGA, KUMAMOTO (JP); YUUKI SAKAI, KUMAMOTO (JP); KUNIHIKO HIKICHI, KUMAMOTO (JP)

(21) Appl. No.: 18/878,105

(22) PCT Filed: Jun. 16, 2023
(86) PCT No.: PCT/JP2023/022366

§ 371 Date: Dec. 23, 2024

(30) Foreign Application Priority Data
Jul. 5, 2022 (JP) 2022-108346

(51) Int. Cl. H10K 59/80

(52) U.S. Cl. CPC H10K 59/80515; H10K 59/80517

(57) ABSTRACT

For example, progress of a chipping into the inside of a display device is effectively suppressed. A display device including: a drive substrate having a pixel region in which a plurality of pixels is formed and a peripheral region provided between the pixel region and an outer edge, in which the drive substrate is provided with a first interface on a first main surface side of the drive substrate in the peripheral region, and is provided with a second interface on a second main surface side of the drive substrate in the peripheral region, and the pixels each include a first electrode, a second electrode disposed to face the first electrode, and an organic layer provided between the first electrode and the second electrode and including a light emitting layer.

### TECHNICAL FIELD

The present disclosure relates to a display device and an electronic apparatus.

### BACKGROUND ART

In an organic electroluminescence (EL) display device using a silicon (Si) substrate or the like as a base, a drive circuit, an organic EL layer, a color filter, and the like are formed on a Si wafer having a diameter of 200 mm, a diameter of 300 mm, or the like. Then, after a glass substrate for protecting the surface is bonded to the Si wafer, the Si wafer is cut into panels of a predetermined size (dicing process). In the dicing process, the Si substrate and the film formed on the substrate is cut, but there is a case where a chipping occurs from an interface of the film or the film itself. This chipping affects the drive circuit and causes a decrease in yield.

As a countermeasure against the above-described chipping, a structure (hereinafter, appropriately referred to as a guard ring) in which wiring layers are vertically laminated is provided on the outer periphery of the panel. A region where the guard ring is provided is also referred to as a guard ring region. For example, Patent Document 1 below describes a semiconductor wafer in which a slit structure is provided on an upper surface of a guard ring region.

### CITATION LIST

### Patent Document

Patent Document 1: Japanese Patent Application Laid-Open No. 2016-26387

### SUMMARY OF THE INVENTION

### Problems to be Solved by the Invention

The organic EL display device generally has a configuration in which an organic EL layer, an electrode layer for allowing the organic EL layer to emit light, a color filter, and the like are laminated. By applying the slit structure described in Patent Document 1 to the concerned organic EL display device, there is a possibility that a variation or the like in film thickness of each layer occurs.

An object of the present disclosure is to provide a display device such as an organic EL display device and an electronic apparatus that can effectively suppress progress of a chipping to the inside.

### Solutions to Problems

The present disclosure is, for example, a display device including:
a drive substrate having a pixel region in which a plurality of pixels is formed and a peripheral region provided between the pixel region and an outer edge, in which
the drive substrate is provided with a first interface on a first main surface side of the drive substrate in the peripheral region, and is provided with a second interface on a second main surface side of the drive substrate in the peripheral region, and
the pixels each include a first electrode, a second electrode disposed to face the first electrode, and an organic layer provided between the first electrode and the second electrode and including a light emitting layer.

### BRIEF DESCRIPTION OF DRAWINGS

FIG. 1 is a diagram referred to in describing the problems to be considered in the present disclosure.

FIG. 2 is a diagram referred to in describing the problems to be considered in the present disclosure.

FIGS. 3A to 3C are diagrams referred to in describing a problem to be considered in the present disclosure.

FIGS. 4A to 4C are diagrams referred to in describing a problem to be considered in the present disclosure.

FIG. 5 is a schematic diagram illustrating an example of an overall configuration of a display device according to an embodiment of the present disclosure.

FIG. 6 is a schematic diagram illustrating an example of an overall configuration of the display device according to the embodiment of the present disclosure.

FIG. 7 is a schematic diagram illustrating an example of an overall configuration of the display device according to the embodiment of the present disclosure.

FIG. 8 is a cross-sectional view of a part of a display region according to the embodiment of the present disclosure.

FIG. 9 is a cross-sectional view for explaining a configuration example of an organic EL layer according to the embodiment of the present disclosure.

FIG. 10 is a cross-sectional view illustrating a cross section taken along a cutting line AA-AA in FIG. 7.

FIG. 11 is a diagram to be referred to in describing a function of the display device according to the embodiment of the present disclosure.

FIG. 12 is a diagram to be referred to in describing a function of the display device according to the embodiment of the present disclosure.

FIG. 13 is a diagram to be referred to in describing an example of a manufacturing method of the display device according to the embodiment of the present disclosure.

FIG. 14 is a diagram to be referred to in describing an example of the manufacturing method of the display device according to the embodiment of the present disclosure.

FIG. 15 is a diagram to be referred to in describing an example of the manufacturing method of the display device according to the embodiment of the present disclosure.

FIG. 16 is a diagram to be referred to in describing an example of the manufacturing method of the display device according to the embodiment of the present disclosure.

FIG. 17A is a schematic cross-sectional view for explaining a first example of a resonator structure. FIG. 17B is a schematic cross-sectional view for explaining a second example of the resonator structure.

FIG. 18A is a schematic cross-sectional view for explaining a third example of the resonator structure. FIG. 18B is a schematic cross-sectional view for explaining a fourth example of the resonator structure.

FIG. 19A is a schematic cross-sectional view for explaining a fifth example of the resonator structure. FIG. 19B is a schematic cross-sectional view for explaining a sixth example of the resonator structure.

FIG. 20 is a schematic cross-sectional view for explaining a seventh example of the resonator structure.

FIGS. 21A, 21B, and 21C are conceptual diagrams each explaining a relationship among a normal line LN passing through the center of a light emitting unit, a normal line LN′ passing through the center of a lens member, and a normal line LN″ passing through the center of a wavelength selection unit.

FIG. 22 is a conceptual diagram for explaining a relationship among the normal line LN passing through the center of the light emitting unit, the normal line LN′ passing through the center of the lens member, and the normal line LN″ passing through the center of the wavelength selection unit.

FIGS. 23A and 23B are conceptual diagrams for explaining a relationship among the normal line LN passing through the center of the light emitting unit, the normal line LN′ passing through the center of the lens member, and the normal line LN″ passing through the center of the wavelength selection unit.

FIG. 24 is a conceptual diagram for explaining a relationship among the normal line LN passing through the center of the light emitting unit, the normal line LN′ passing through the center of the lens member, and the normal line LN″ passing through the center of the wavelength selection unit.

FIG. 25A is a front view illustrating an example of an external appearance of a digital still camera. FIG. 25B is a back view illustrating an example of an external appearance of the digital still camera.

FIG. 26 is a perspective view illustrating an example of an external appearance of a head-mounted display.

FIG. 27 is a perspective view illustrating an example of an external appearance of a television device.

FIG. 28 is a perspective view illustrating an example of an external appearance of a see-through head-mounted display.

FIG. 29 is a perspective view illustrating an example of an external appearance of a smartphone.

FIG. 30A is a view illustrating an example of an internal state of a vehicle as viewed from the rear to the front of the vehicle. FIG. 30B is a view illustrating an example of an internal state of the vehicle as viewed from the oblique rear to the oblique front of the vehicle.

FIG. 31 is a diagram for describing a modification.

FIG. 32 is a diagram for describing a modification.

FIG. 33 is a diagram for describing a modification.

FIG. 34 is a diagram for describing a modification.

FIG. 35 is a diagram for describing a modification.

FIG. 36 is a diagram for describing a modification.

FIG. 37 is a diagram for describing a modification.

FIGS. 38A and 38B are diagrams for describing a modification.

### MODE FOR CARRYING OUT THE INVENTION

Hereinafter, an embodiment and the like of the present disclosure will be described below with reference to the drawings. Note that the description will be given in the following order.

### Problems to be Considered in the Present Disclosure

### Embodiment

### Application Examples

### <Modifications>

The embodiment and the like to be described below are preferred specific examples of the present disclosure, and the content of the present disclosure is not limited to the embodiment and the like. Note that, in the following description, components having substantially the same functional configuration are denoted by the same reference sign, and redundant description will be omitted as appropriate. Furthermore, in order to prevent the illustration from being complicated, there is a case where only a part of the configuration is denoted by reference numerals, or there is a case where the illustration is simplified or enlarged/reduced. Furthermore, directions of up and down, left and right, and the like are defined in consideration of convenience of description, but the present disclosure is not limited by these directions in the description.

### Problems to be Considered in the Present Disclosure

First, problems to be considered in the present disclosure will be described below to facilitate understanding of the present disclosure. A display device (display device 1) which is an organic EL display device having a general configuration has a configuration in which an interlayer insulating layer and the like are formed on a substrate such as a silicon substrate (not illustrated). At the time of dicing the substrate, cracks and chippings (hereinafter, simply collectively referred to as chippings) occur in some cases inside the display device 1. Furthermore, it is assumed that moisture enters the inside of the display device 1 from the end of the display device 1 after the dicing. When moisture enters the inside of the display device 1, there is a possibility that corrosion or the like of wirings in the inside occurs and the reliability of the display device 1 is deteriorated.

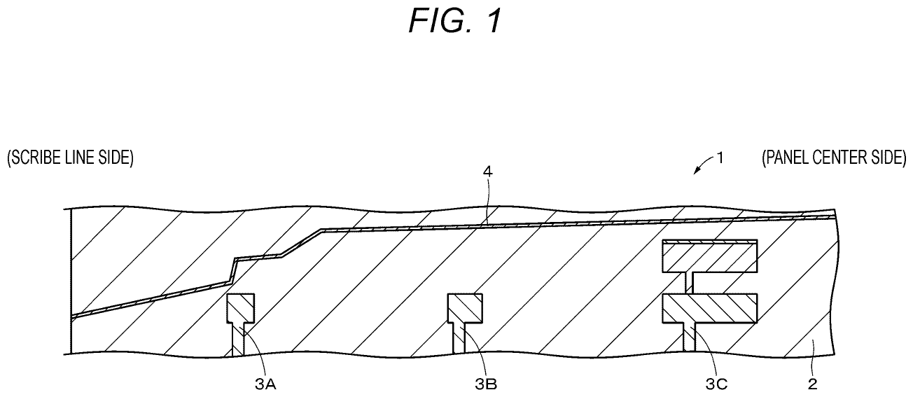

FIG. 1 is a cross-sectional view illustrating a cross section of a part of the display device 1 after the dicing. In FIG. 1, the left side of the drawing is a scribe line side, and the right side thereof is a panel center side of the display device 1. The display device 1 includes an interlayer insulating layer 2, and the interlayer insulating layer 2 is provided with three guard rings (guard rings 3A, 3B, 3C) from the scribe line side toward the panel center side. In a case where it is not necessary to distinguish the individual guard rings, the guard rings are collectively referred to as the guard rings 3 as appropriate.

FIG. 1 further schematically illustrates a chipping 4 that has progressed (propagated) in the display device 1. In the configuration illustrated in FIG. 1, that is, in the configuration in which only the plurality of guard rings are provided, there is no guard ring in the upper area of the interlayer insulating layer 2. Therefore, as illustrated in FIG. 1, there is a possibility that the chipping 4 progresses toward the panel center side through the upper side of the interlayer insulating layer 2.

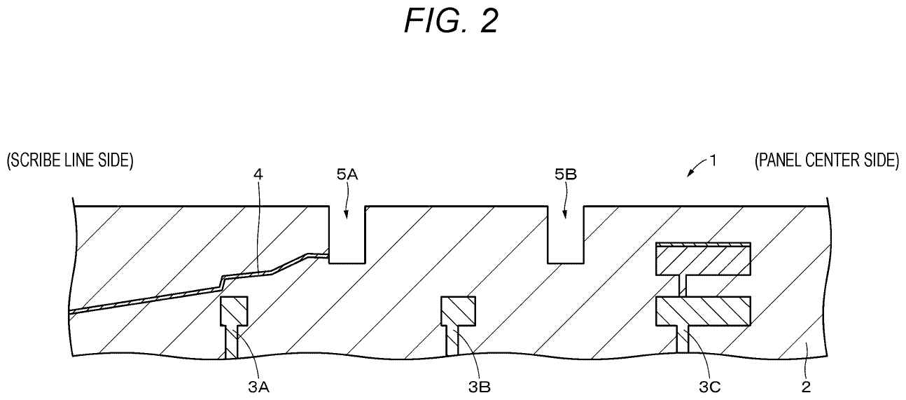

In order to avoid such inconvenience, a technique of providing a slit on the upper surface of the interlayer insulating layer 2 is conceivable. For example, as illustrated in FIG. 2, slits 5A and 5B are formed on the upper surface of the interlayer insulating layer 2. With this arrangement, even in a case where the chipping 4 progresses in the upper part of the interlayer insulating layer 2, the progress of the chipping 4 can be suppressed by the slit 5A or the slit 5B.

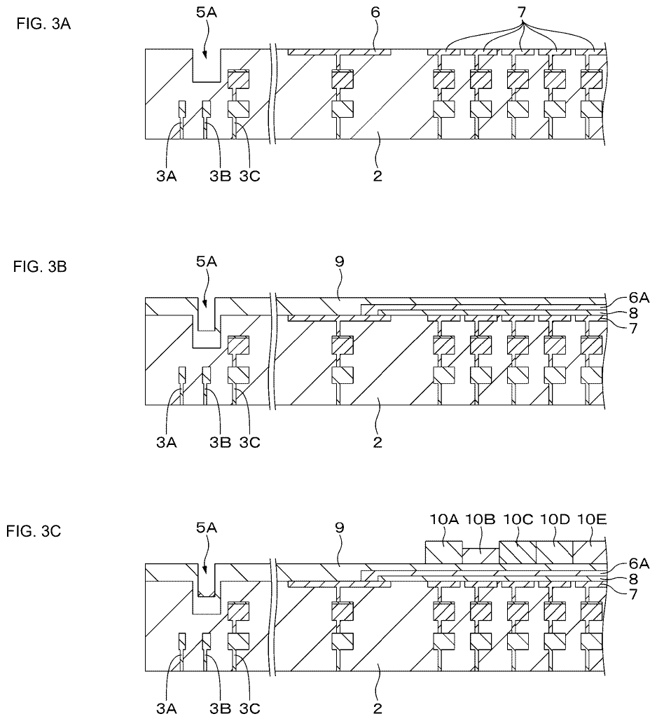

On the other hand, the structure in which the slit is simply provided possibly causes inconvenience in a process of integrating each of the layers constituting the display device 1. This point will be described below. FIGS. 3A, 3B, and 3C are diagrams illustrating a part of the configuration in a manufacturing process of the display device 1 in a simplified manner.

As illustrated in FIG. 3A, the interlayer insulating layer 2 is provided with the guard rings 3 and the slit 5A. Note that, although only the slit 5A is illustrated in the present example, the slit 5B may be provided as described above. Furthermore, a cathode contact 6 and an anode electrode 7 are formed such that these contacts are exposed on the upper side of the interlayer insulating layer 2.

In the subsequent step, as illustrated in FIG. 3B, an organic EL layer 8 is formed on the anode electrode 7. Then, a cathode electrode 6A is formed on the organic EL layer 8 so as to sandwich the organic EL layer 8 and face the anode electrode 7. A cathode electrode 9A is connected to the above-described cathode contact 6. Then, a protective layer 9 for protecting the organic EL layer 8 is formed on the cathode electrode 6A.

In the subsequent step, as shown in FIG. 3C, a color filter 10 is formed on the protective layer 9. In FIG. 3C, five color filters (color filters 10A, 10B . . . 10E) are illustrated, but the present invention is not limited thereto. Note that, in a case where it is not necessary to distinguish the individual color filters, the color filters are collectively referred to as the color filters 10 as appropriate.

As material of the color filter 10, for example, solution-based material is used. Furthermore, the color filter 10 is formed to have a constant film thickness by, for example, a spin coating method. At the time of forming the color filter 10 by the spin coating method, a part of the solution-based material flows into the slit 5A or is accumulated near the boundary of the slit 5A, which causes application unevenness to occur and the film thickness to fluctuate. FIG. 3C illustrates a state in which the film thickness of the color filter 10B among the five color filters 10 has been reduced. As described above, by providing the slit 5A before the organic EL layer 8 is formed, the film thicknesses between the color filters 10 becomes uneven, which causes adverse effects such as quality deterioration of the display device 1.

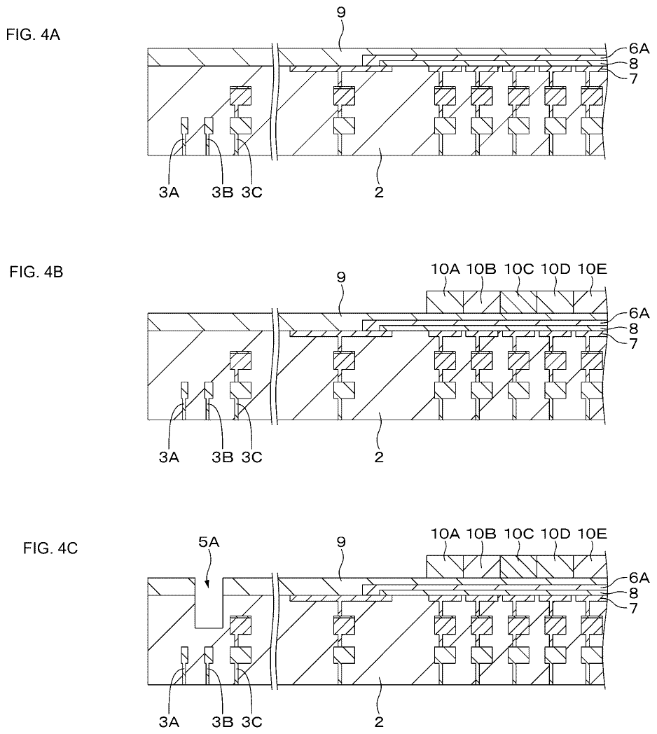

Therefore, it is conceivable to form the slit 5A after forming the organic EL layer 8. For example, as illustrated in FIG. 4A, the organic EL layer 8, the cathode electrode 6A, and the protective layer 9 are formed. In the subsequent step, as illustrated in FIG. 4B, the color filter 10 is formed on the upper surface of the protective layer 9. In the subsequent step, as illustrated in FIG. 4C, the slit 5A is formed on the protective layer 9 and the interlayer insulating layer 2. In this manner, by the manufacturing method of providing the slit 5A after the organic EL layer 8 is formed, the above-described variation in film thickness does not occur because the slit 5A is not formed at the time of forming the color filter 10.

However, in the step of forming the slit 5A, there is a case where the atmosphere becomes a high temperature of 100 degrees or more. Such a high temperature possibly damages the material constituting the organic EL layer 8. As described above, in order to apply the conventional guard ring structure, which has been applied to the semiconductor wafer or the like, to the organic EL display device, it is necessary to prevent the above-described inconvenience in integration. In consideration of the above points, the present disclosure will be described in detail with reference to an embodiment.

### Embodiment

### [Configuration Example of Display Device]

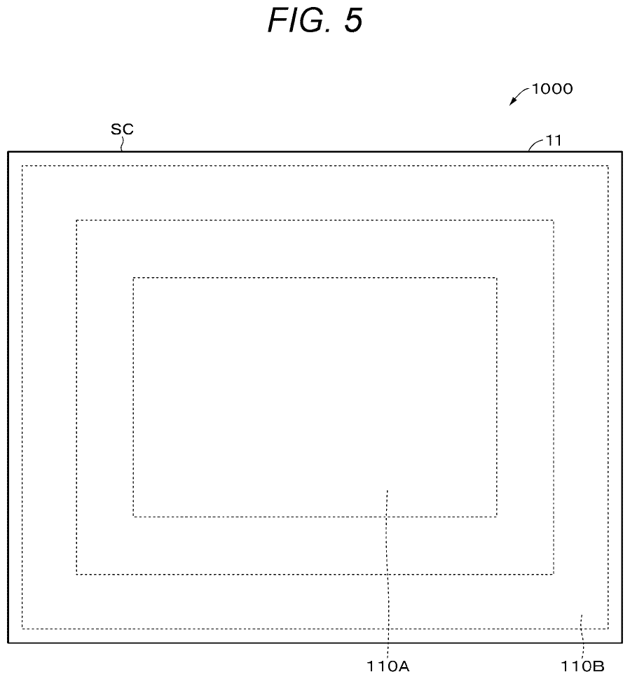

FIGS. 5, 6, and 7 are schematic diagrams illustrating an example of an overall configuration of a display device (display device 1000) according to an embodiment of the present disclosure. As illustrated in FIG. 5, the display device 1000 includes a drive substrate 11. The drive substrate 11 has, on one main surface thereof, a display region 110A which is an example of a pixel region, and a peripheral region 110B provided near a peripheral edge between the display region 110A and an outer edge of the drive substrate 11. The peripheral region 110B means a region close to the outer edge of the drive substrate 11. Here, the outer edge of the drive substrate 11 coincides with a scribe line SC at the time when the drive substrate 11 is diced in the present embodiment, but may not strictly coincide with the scribe line SC and may be in the vicinity thereof.

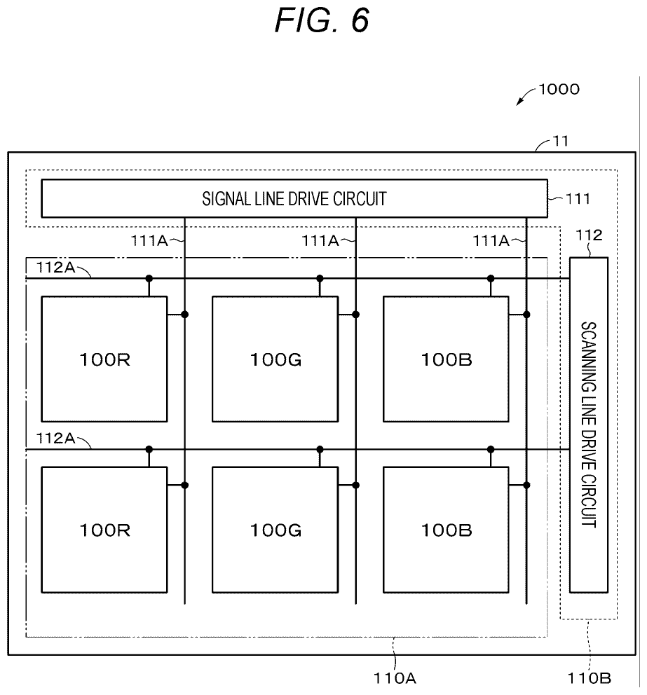

A plurality of pixels is provided in the display region 110A. Specifically, as illustrated in FIG. 6, in the display region 110A, a plurality of subpixels 100R, 100G, and 100B is two-dimensionally arranged in a prescribed arrangement pattern such as a matrix.

The subpixel 100R displays red, the subpixel 100G displays green, and the subpixel 100B displays blue. Note that, in a case where the subpixels 100R, 100G, and 100B are collectively referred to without being particularly distinguished from each other in the following description, the subpixels are referred to as the subpixels 100. A combination of the adjacent subpixels 100R, 100G, and 100B constitutes one pixel. FIG. 6 illustrates an example in which a combination of the three subpixels 100R, 100G, and 100B aligned in a row direction (horizontal direction) constitutes one pixel, but the alignment of the subpixels 100R, 100G, and 100B is not limited thereto.

In the peripheral region 110B, a signal line drive circuit 111 and a scanning line drive circuit 112, which are drivers for video display, are provided. Pads for connecting to these drive circuits may be provided in the peripheral region 110B. The signal line drive circuit 111 supplies a signal voltage of a video signal corresponding to luminance information supplied from a signal supply source (not illustrated), to the subpixel 100 selected via a signal line 111A. The scanning line drive circuit 112 is constituted of a shift register or the like that sequentially shifts (transfers) a start pulse in synchronization with an input clock pulse. The scanning line drive circuit 112 scans the video signal written to each of the subpixels 100 row by row and sequentially supplies the scanned signals to corresponding ones of scanning lines 112A.

The display device 1000 may be a microdisplay. The display device 1000 may be provided in a virtual reality (VR) device, a mixed reality (MR) device, an augmented reality (AR) device, an electronic view finder (EVF), a small projector, or the like.

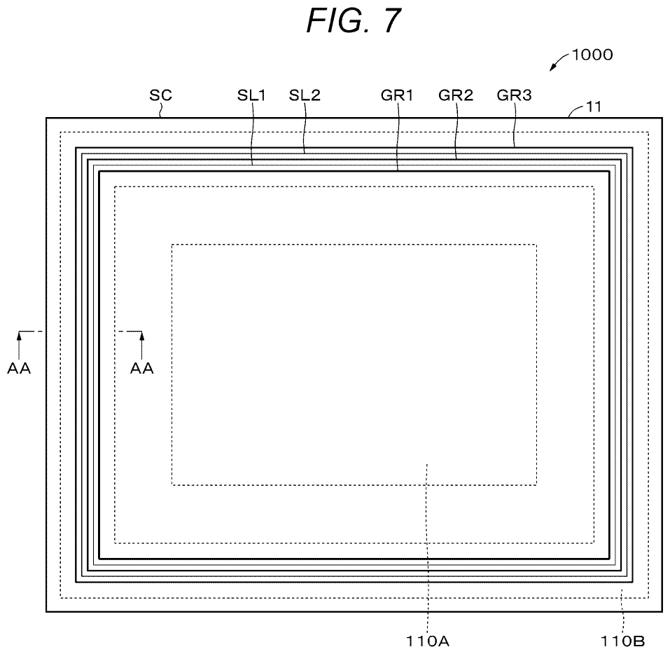

As illustrated in FIG. 7, a guard ring and a slit structure are provided on the outer side of the peripheral region 110B, more specifically, on the outer side of the signal line drive circuit 111 and the scanning line drive circuit 112 (on the scribe line SC side). For example, three guard rings (a first guard ring GR1, a second guard ring GR2, and a third guard ring GR3) are provided from the center toward the outer side of the drive substrate 11. Furthermore, two slit structures (a first slit structure SL1 and a second slit structure SL2) are formed from the center toward the outer side of the drive substrate 11. The first slit structure SL1 is formed between the first guard ring GR1 and the second guard ring GR2. Furthermore the second slit structure SL2 is formed between the second guard ring GR2 and the third guard ring GR3. In a case where the drive substrate 11 is viewed from above, each guard ring and each slit structure are continuously disposed to form a frame shape.

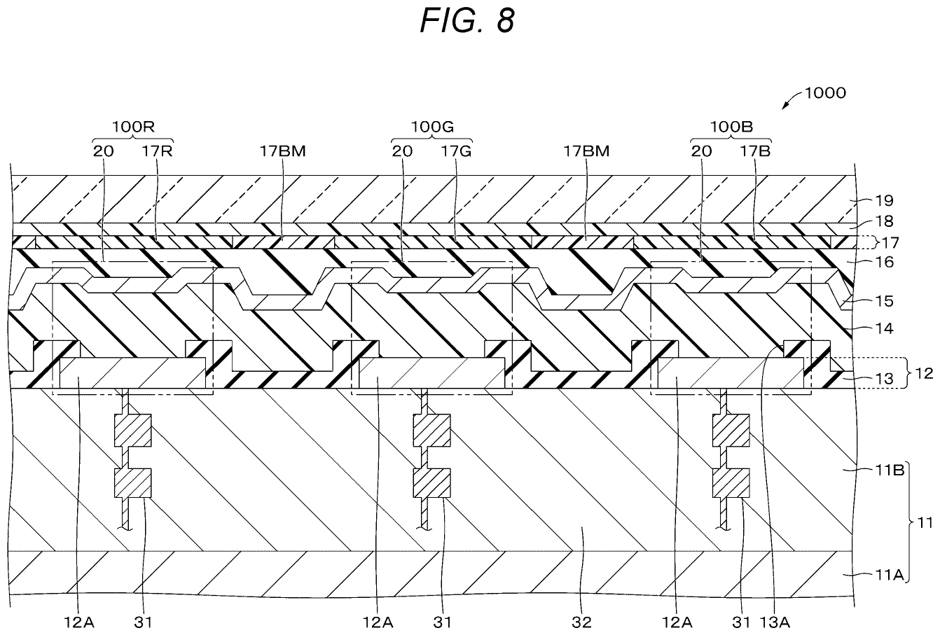

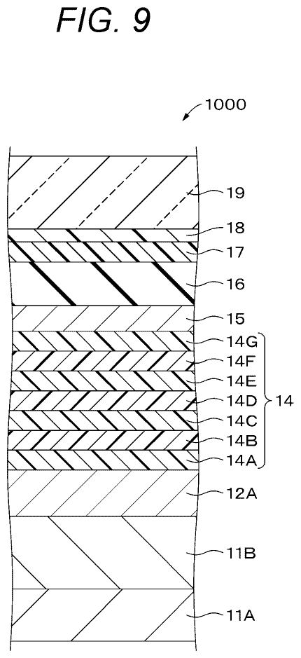

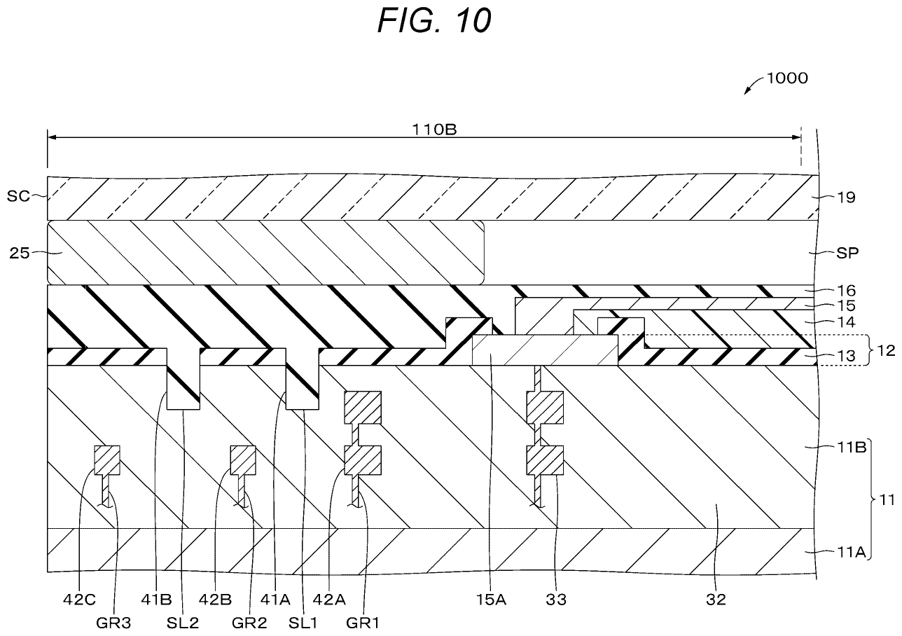

Next, a configuration example of the display device 1000 according to the embodiment will be described in detail with reference to FIGS. 8, 9, and 10. FIG. 8 is a cross-sectional view of a part of the display region 110A, FIG. 9 is a cross-sectional view for explaining a configuration example of an organic EL layer (organic EL layer 14) to be described later, and FIG. 10 is a cross-sectional view illustrating a cross section of a peripheral region 110B in a case where the region is cut along a cutting line AA-AA in FIG. 7.

As illustrated in FIG. 8, the display device 1000 includes the drive substrate 11, a first electrode layer 12, an inter-pixel insulating layer 13, the organic EL layer 14, a second electrode layer 15, a protective layer 16, a color filter 17, a filling resin layer 18, and a counter substrate 19.

The display device 1000 is a top emission type display device. The counter substrate 19 side of the display device 1000 is the top side, and the drive substrate 11 side of the display device 1000 is the bottom side. In the following description, in each layer constituting the display device 1000, a surface (side) on the top side of the display device 1000 is referred to as a first main surface (first main surface side), and a surface (side) on the bottom side of the display device 1000 is referred to as a second main surface (second main surface side) as appropriate.

The display device 1000 includes a plurality of light emitting elements 20. The plurality of light emitting elements 20 includes the first electrode layer 12, the organic EL layer 14 as an example of an organic layer including a light emitting layer, and the second electrode layer 15. The light emitting element 20 is, for example, a white light emitting element such as a white OLED or a white Micro-OLED (MOLED). As a coloring method in the display device 1000, a method using a white light emitting element and the color filter 17 is used.

### (Drive Substrate)

The drive substrate 11 is a so-called backplane and drives the plurality of light emitting elements 20. The drive substrate 11 includes, for example, a base material 11A and a drive circuit layer 11B laminated on the base material 11A. The drive circuit layer 11B may be laminated and formed on the base material 11A, or a part thereof may be directly formed on the base material 11A by a semiconductor process.

The base material 11A may be a semiconductor substrate such as a silicon substrate, may be a glass substrate or quartz having low moisture and oxygen permeability, or an insulator substrate such as resin. The semiconductor substrate includes, for example, amorphous silicon, polycrystalline silicon, monocrystalline silicon, or the like. As a specific example, the glass substrate includes, for example, high strain point glass, soda glass, borosilicate glass, forsterite, lead glass, quartz glass, or the like. Furthermore, specific examples of the resin substrate include, for example, at least one kind selected from the group including polymethyl methacrylate, polyvinyl alcohol, polyvinyl phenol, polyethersulfone, polyimide, polycarbonate, polyethylene terephthalate, polyethylene naphthalate, and the like. The base material 11A has, for example, a thin plate shape. The base material 11A may have flexibility.

The drive circuit layer 11B includes, for example, a drive circuit such as a transistor (not illustrated) electrically connected to the first electrode layer 12, a wiring layer 31, and an interlayer insulating layer 32 disposed between the wiring layer 31. The first electrode layer 12 is connected to the transistor via the wiring layer 31 by a known connection structure. The drive circuit formed in the drive circuit layer 11B is, for example, an active matrix-type pixel drive circuit.

The wiring layer 31 may be one wiring layer or may have a configuration in which a plurality of wiring layers are connected through via layers. As the wiring layer 31, a conductive metal such as copper (Cu), aluminum (Al), or a combination thereof is applied.

Examples of the interlayer insulating layer 32 include an interlayer insulating layer including an inorganic substance such as silicon oxide (SiOx), silicon nitride (SiN), or silicon oxynitride (SiON), or an organic substance such as polyimide or polyacryl. The interlayer insulating layer 32 may be located on the top side, and may include a flat layer (layer referred to as a flattening layer) serving as a base at the time of forming the first electrode layer 12. In this example, the upper surface side of the drive circuit layer 11B corresponds to the first main surface side of the drive substrate 11, and the bottom surface of the base material 11A corresponds to the second main surface side of the drive substrate 11.

### (First Electrode Layer)

The first electrode layer 12 is provided on the first main surface of the drive substrate 11, that is, on the interlayer insulating layer 32. The first electrode layer 12 is an anode. When a voltage is applied between the first electrode layer 12 and the second electrode layer 15, holes are injected from the first electrode layer 12 into the organic EL layer 14. The first electrode layer 12 also functions as a reflection layer, and preferably includes a material having as high a reflectance as possible and a large work function in order to enhance the light emission efficiency. The first electrode layer 12 includes a plurality of electrodes 12A. The plurality of electrodes 12A is electrically separated between the adjacent light emitting elements 20. The plurality of electrodes 12A shares the organic EL layer 14. The plurality of electrodes 12A is two-dimensionally arranged in a prescribed arrangement pattern such as a matrix shape.

The electrode 12A includes at least one of a metal layer and a metal oxide layer. More specifically, the electrode 12A includes a single layer film of a metal layer or a metal oxide layer, or a laminated film of a metal layer and a metal oxide layer. In a case where the electrode 12A includes the laminated film, the metal oxide layer may be provided on the organic EL layer 14 side, or the metal layer may be provided on the organic EL layer 14 side, but from the viewpoint of including a layer having a high work function adjacent to the organic EL layer 14, the metal oxide layer is preferably provided on the organic EL layer 14 side.

The metal layer includes, for example, at least one metal element selected from the group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may include the at least one metal element described above as a constituent element of an alloy. Specific examples of the alloy include an aluminum alloy and a silver alloy. Specific examples of the aluminum alloy include, for example, AlNd or AlCu.

The metal oxide layer includes, for example, a transparent conductive oxide (TCO). The transparent conductive oxide includes, for example, at least one kind selected from the group including indium-containing transparent conductive oxides (hereinafter, referred to as “indium-based transparent conductive oxides”), tin-containing transparent conductive oxides (hereinafter, referred to as “tin-based transparent conductive oxides”), and zinc-containing transparent conductive oxides (hereinafter, referred to as “zinc-based transparent conductive oxides”).

The indium-based transparent conductive oxide includes, for example, indium tin oxide (ITO), indium zinc oxide (IZO), indium gallium oxide (IGO), or indium gallium zinc oxide (IGZO), fluorine-doped indium oxide (IFO). Among these transparent conductive oxides, indium tin oxide (ITO) is particularly preferable. This is because the indium tin oxide (ITO) has a particularly low hole injection barrier into the organic EL layer 14 as a work function, and thus, the drive voltage of the display device 1000 can be particularly reduced. The tin-based transparent conductive oxides include, for example, tin oxide, antimony-doped tin oxide (ATO), or fluorine-doped tin oxide (FTO). The zinc-based transparent conductive oxides include, for example, zinc oxide, aluminum-doped zinc oxide (AZO), boron-doped zinc oxide, or gallium-doped zinc oxide (GZO).

### (Second Electrode Layer)

The second electrode layer 15 is provided to face the first electrode layer 12. The second electrode layer 15 is provided as an electrode common to all the subpixels 100 in the display region 110A. The second electrode layer 15 is a cathode. When a voltage is applied between the first electrode layer 12 and the second electrode layer 15, electrons are injected from the second electrode layer 15 into the organic EL layer 14. The second electrode layer 15 is a transparent electrode having transparency to light generated in the organic EL layer 14. Here, the transparent electrode also includes a semi-transmissive reflection layer. The second electrode layer 15 preferably includes a material having as high transparency as possible and a small work function in order to enhance light emission efficiency.

The second electrode layer 15 includes, for example, at least one of a metal layer or a metal oxide layer. More specifically, the second electrode layer 15 includes a single layer film of a metal layer or a metal oxide layer, or a laminated film of a metal layer and a metal oxide layer. In a case where the second electrode layer 15 includes the laminated film, the metal layer may be provided on the organic EL layer 14 side, or the metal oxide layer may be provided on the organic EL layer 14 side, but from the viewpoint of including a layer having a low work function adjacent to the organic EL layer 14, the metal layer is preferably provided on the organic EL layer 14 side.

The metal layer includes, for example, at least one metal element selected from a group including magnesium (Mg), aluminum (Al), silver (Ag), calcium (Ca), and sodium (Na). The metal layer may include the at least one metal element described above as a constituent element of an alloy. Specific examples of the alloy includes an MgAg alloy, an MgAl alloy, an AlLi alloy, or the like. The metal oxide layer includes a transparent conductive oxide. As the transparent conductive oxide, a material similar to the above-described transparent conductive oxide of the electrode 12A can be exemplified.

### (EL Layer)

The organic EL layer 14 is provided between the first electrode layer 12 and the second electrode layer 15. The organic EL layer 14 is continuously provided over all the subpixels 100 (that is, the plurality of electrodes 12A) in the display region 110A, and is provided as a layer common to all the subpixels 100 in the display region 110A. The organic EL layer 14 is configured to, for example, emit white light. Needless to say, the organic EL layer 14 may emit light of other colors.

As illustrated in FIG. 9, the organic EL layer 14 has, for example, a configuration in which a hole transport layer 14A, a red light emitting layer 14B, a light emitting separation layer 14C, a blue light emitting layer 14D, a green light emitting layer 14E, an electron transport layer 14F, and an electron injection layer 14G are laminated in this order from the first electrode layer 12 toward the second electrode layer 15.

The hole transport layer 14A is adjacent to the first electrode layer 12 and the inter-pixel insulating layer 13. The hole transport layer 14A is a layer for enhancing hole transport efficiency to each of the light emitting layers 14B, 14D, and 14E. The hole transport layer 14A includes, for example, α-NPD(N,N′-di(1-naphthyl)-N,N′-diphenyl-[1,1′-biphenyl]-4,4′-diamine).

The electron transport layer 14F is a layer for enhancing electron transport efficiency to each of the light emitting layers 14B, 14D, and 14E. The electron transport layer 14F includes, for example, at least one kind selected from a group including BCP (2,9-dimethyl-4,7-diphenyl-1,10-phenanthroline), Alq3 (aluminum quinolinol complex), Bphen (bathophenanthroline), and the like.

The electron injection layer 14G is a layer for enhancing electron injection from the cathode. The electron injection layer 14G includes, for example, a single substance of an alkali metal or an alkaline earth metal or a compound including the same, specifically, for example, lithium (Li) or lithium fluoride (LiF), or the like.

The light emitting separation layer 14C is a layer for adjusting injection of carriers into each of the light emitting layers 14B, 14D, and 14E, and light emission balance of each color is adjusted by injecting electrons or holes into each of the light emitting layers 14B, 14D, and 14E via the light emitting separation layer 14C. The light emitting separation layer 14C includes, for example, 4,4′-bis[N-(1-naphthyl)-N-phenyl-amino]biphenyl derivative, or the like.

The red light emitting layer 14B, the blue light emitting layer 14D, and the green light emitting layer 14E are layers that emit red light, blue light, and green light, respectively, by having an electric field applied thereto to cause recombination between the holes injected from the electrode 12A and the electrons injected from the second electrode layer 15.

The red light emitting layer 14B includes, for example, a red light emitting material. The red light emitting material may be fluorescent or phosphorescent. Specifically, the red light emitting layer 14B includes, for example, a mixture of 4,4-bis(2,2-diphenylvinin)biphenyl (DPVBi) and 2,6-bis[(4′-methoxydiphenylamino)styryl]-1,5-dicyanonaphthalene (BSN).

The blue light emitting layer 14D includes, for example, a blue light emitting material. The blue light emitting material may be fluorescent or phosphorescent. Specifically, the blue light emitting layer 14D includes, for example, a mixture of 4,4′-bis[2-{4-(N,N-diphenylamino)phenyl}vinyl]biphenyl with DPVBi (DPAVBi).

The green light emitting layer 14E includes, for example, a green light emitting material. The green light emitting material may be fluorescent or phosphorescent. Specifically, the green light emitting layer 14E includes, for example, a mixture of DPVBi and coumarin 6. Note that the light emitting layer may contain a light emitting material having a complementary color relationship, such as a blue light emitting material and a yellow light emitting material.

### (Inter-Pixel Insulating Layer)

The inter-pixel insulating layer 13 is provided on the first main surface of the drive substrate 11 and between the adjacent electrodes 12A. The inter-pixel insulating layer 13 insulates the separated individual electrodes 12A from each other. The inter-pixel insulating layer 13 has a plurality of openings 13A. Each of the plurality of openings 13A is provided corresponding to each subpixel 100. More specifically, each of the plurality of openings 13A is provided on the first main surface (surface facing the second electrode layer 15) of each of the separated electrodes 12A. The electrode 12A and the organic EL layer 14 are in contact with each other through the opening 13A.

The inter-pixel insulating layer 13 may be an organic insulating layer, an inorganic insulating layer, or a laminate constituted of these layers. The organic insulating layer includes, for example, at least one kind selected from the group including polyimide-based resin, acrylic resin, novolac-based resin, and the like. The inorganic insulating layer includes, for example, at least one kind selected from the group including silicon oxide (SiOx), silicon nitride (SiNx), silicon oxynitride (SiOxNy), and the like.

### (Protective Layer)

The protective layer 16 is provided on the first main surface of the second electrode layer 15 and covers the plurality of light emitting elements 20. The protective layer 16 shields the light emitting element 20 from the outside air, and prevents moisture infiltration into the light emitting element 20 from the external environment. Furthermore, in a case where the second electrode layer 15 is constituted of a metal layer, the protective layer 16 may have a function of preventing oxidation of the metal layer.

The protective layer 16 includes, for example, an inorganic material or a polymer resin having low hygroscopicity. The protective layer 16 may have a single layer structure or a multilayer structure. In a case where the thickness of the protective layer 16 is to be increased, it is preferable to have a multilayer structure. This is to alleviate the internal stress in the protective layer 16. The inorganic material includes, for example, at least one kind selected from a group including silicon oxide (SiOx), silicon nitride (SiNx), silicon oxynitride (SiOxNy), titanium oxide (TiOx), aluminum oxide (AlOx), and the like. The polymer resin includes, for example, at least one kind selected from a group including a thermosetting resin, an ultraviolet curable resin, and the like.

### (Color Filter)

The color filter 17 is provided on the first main surface of the protective layer 16. The color filter 17 is, for example, an on chip color filter (OCCF). The color filter 17 includes, for example, a red filter 17R, a green filter 17G, and a blue filter 17B. Each of the red filter 17R, the green filter 17G, and the blue filter 17B is provided to face the light emitting element 20. The red filter 17R and the light emitting element 20 constitute the subpixel 100R, the green filter 17G and the light emitting element 20 constitute the subpixel 100G, and the blue filter 17B and the light emitting element 20 constitute the subpixel 100B.

White light emitted from the light emitting elements 20 in the subpixels 100R, 100G, and 100B is transmitted through the red filter 17R, the green filter 17G, and the blue filter 17B described above to cause red light, green light, and blue light to be respectively emitted from the display surface. Furthermore, a light shielding layer 17BM may be provided between the color filters 17R, 17G, and 17B, that is, in a region between the subpixels 100. Note that the color filter 17 is not limited to the on chip color filter, and may be provided on the second main surface of the counter substrate 19 (surface facing the organic EL layer 14).

### (Filling Resin Layer)

The filling resin layer 18 is provided between the color filter 17 and the counter substrate 19. The filling resin layer 18 has a function as a bonding layer for bonding the color filter 17 and the counter substrate 19 together. The filling resin layer 18 includes, for example, at least one kind selected from a group including a thermosetting resin, an ultraviolet curable resin, and the like.

### (Counter Substrate)

The counter substrate 19 is provided to face the drive substrate 11. More specifically, the counter substrate 19 is provided in a manner that a second surface of the counter substrate 19 and the first main surface of the drive substrate 11 face each other. The counter substrate 19 and the filling resin layer 18 seal the light emitting element 20, the color filter 17, and the like. The counter substrate 19 includes a material such as glass transparent to light of each color emitted from the color filter 17.

As illustrated in FIG. 10, in the vicinity of the outer edge of the peripheral region 110B, a sealant 25 is provided between the counter substrate 19 and a surface of the drive substrate 11 on the side facing the counter substrate 19. The sealant 25 bonds together a peripheral edge of the facing surface of the counter substrate 19 and a peripheral edge of the facing surface of the drive substrate 11 (more specifically, the protective layer 16 laminated on the peripheral edge). As the sealant 25, for example, a thermosetting resin can be applied. The color filter 17 and the filling resin layer 18 described above are disposed in a gap SP formed by the thickness of the sealant 25. Note that the sealant 25 may have the same configuration as that of the filling resin layer 18.

Furthermore, as illustrated in FIG. 10, a cathode contact 15A is provided on the first main surface of the drive circuit layer 11B in the peripheral region 110B. The second electrode layer 15 is connected to the cathode contact 15A. The cathode contact 15A is connected to a drive circuit (not illustrated) via a wiring layer 33 provided in the drive circuit layer 11B.

A first slit structure SL1 and a second slit structure SL2 are provided on the first main surface side of the drive substrate 11 in the peripheral region 110B. More specifically, the first slit structure SL1 and the second slit structure SL2 are provided on the outer side of the cathode contact 15A (on the scribe line SC side) and below the sealant 25. The first slit structure SL1 is provided on the inner side, and the second slit structure SL2 is provided on the outer side of the first slit structure SL1. In the present embodiment, the first slit structure SL1 and the second slit structure SL2 constitute a first recess.

The first slit structure SL1 and the second slit structure SL2 are provided in a manner that at least the interlayer insulating layer 32 is included. In the present embodiment, because the inter-pixel insulating layer 13 is formed on the first main surface of the interlayer insulating layer 32, the first slit structure SL1 and the second slit structure SL2 are formed down to, for example, predetermined depths of the inter-pixel insulating layer 13 and the interlayer insulating layer 32. Note that the depths of the first slit structure SL1 and the second slit structure SL2 may be the same as or different from each other.

The first slit structure SL1 and the second slit structure SL2 are filled with the protective layer 16. In the present embodiment, an interface 41A is formed by the first slit structure SL1. Here, the interface means a boundary between different layers. The materials constituting each of the different layers may be the same kind of material or different kinds of materials, and furthermore, one layer may be an air layer. Examples of each layer include a single inorganic film, a laminated inorganic film, a single organic film, a laminated organic film, a single metal layer, a laminated metal layer, a combination thereof, or the like. In the present embodiment, the boundary between the material constituting the interlayer insulating layer 32 and the material constituting the protective layer 16, that is, the boundary between the dissimilar materials is the interface 41A. Similarly, in the present embodiment, an interface 41B is formed by the second slit structure SL2. In the present embodiment, the interface 41A and the interface 41B constitute a first interface.

The first guard ring GR1 is provided, for example, in a region between the first slit structure SL1 and the wiring layer 33 in the interlayer insulating layer 32. The second guard ring GR2 is provided, for example, on the lower side of a region between the first slit structure SL1 and the second slit structure SL2 in the interlayer insulating layer 32. The third guard ring GR3 is provided, for example, on the lower side of a region between the second slit structure SL2 and the scribe line SC in the interlayer insulating layer 32. The first guard ring GR1, the second guard ring GR2, and the third guard ring GR3 are not intended to be used as wirings but are dummy wirings for preventing moisture infiltration or the like into the display device 1000. In the present embodiment, the first guard ring GR1, the second guard ring GR2, and the third guard ring GR3 constitute a wiring structure.

The first guard ring GR1 has, for example, two wiring layers, and these wiring layers are configured to be continuous by a via layer or the like. The second guard ring GR2 has, for example, one wiring layer and a via layer provided for the wiring layer. The third guard ring GR3 has one wiring layer and a via layer provided for the wiring layer. Note that the number of wiring layers included in each guard ring can be set to any number of one or more. Copper, aluminum, or the like is used for the wiring layer and the via layer. Furthermore, the second main surface side end of the via layer may extend to the interlayer insulating layer 32 or may extend to the base material 11A side.

The first guard ring GR1 forms an interface 42A. Specifically, the interface 42A is formed by the boundary between the material constituting the first guard ring GR1 and the material constituting the interlayer insulating layer 32, that is, the boundary between the dissimilar materials. Furthermore, the second guard ring GR2 forms an interface 42B. Specifically, the interface 42B is formed by the boundary between the material constituting the second guard ring GR2 and the material constituting the interlayer insulating layer 32, that is, the boundary between the dissimilar materials. Furthermore, the third guard ring GR3 forms an interface 42C. Specifically, the interface 42C is formed by the boundary between the material constituting the third guard ring GR3 and the material constituting the interlayer insulating layer 32, that is, the boundary between the dissimilar materials. In the present embodiment, the interface 42A, the interface 42B, and the interface 42C constitute a second interface.

### [Function]

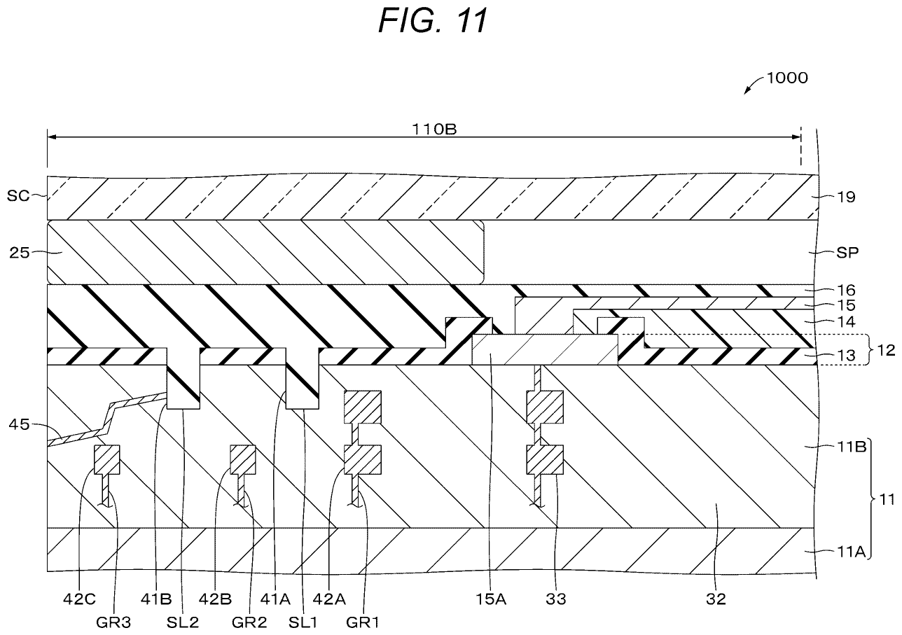

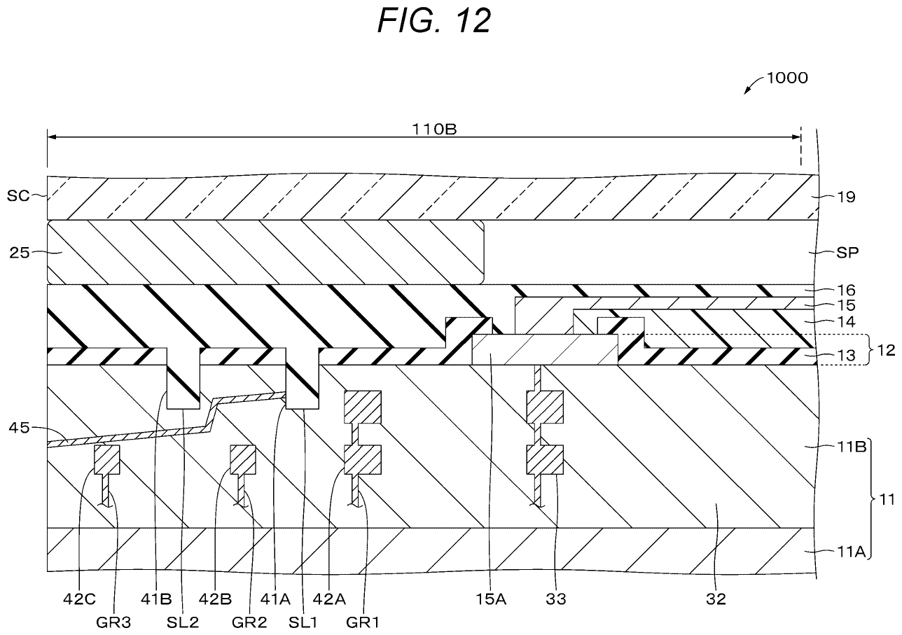

According to the display device 1000 of the present embodiment, a chipping (chipping 45) can be prevented from progressing to the inside of the display device 1000. As schematically illustrated in FIGS. 11 and 12, even in a case where the chipping 45 progresses in the upper part of the interlayer insulating layer 32 in which the first guard ring GR1, the second guard ring GR2, and the third guard ring GR3 are not formed, the progress of the chipping 45 is suppressed by the first slit structure SL1 or the second slit structure SL2.

### [Manufacturing Method of Display Device]

Hereinafter, an example of a manufacturing method of the display device 1000 according to the embodiment of the present disclosure will be described.

First, the drive circuit layer 11B including the wiring layer 31, the interlayer insulating layer 32, the wiring layer 33, the first guard ring GR1, the second guard ring GR2, and the third guard ring GR3 is formed on the first main surface of the base material 11A.

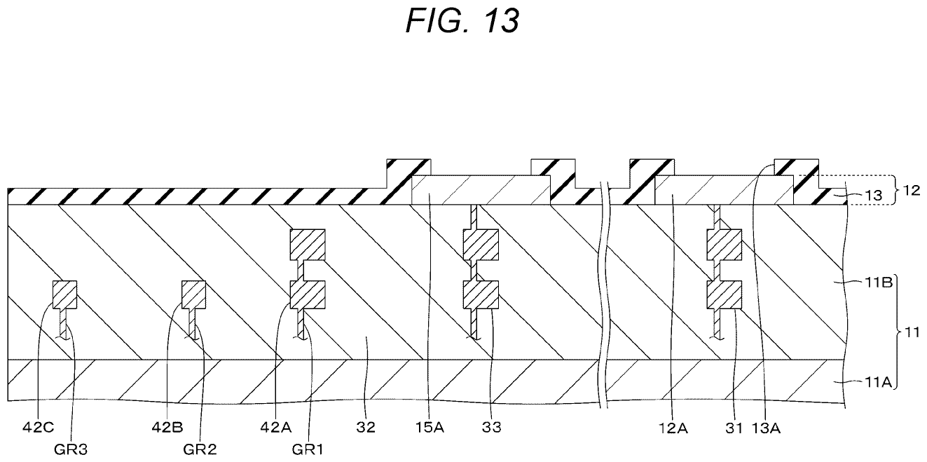

Next, as shown in FIG. 13, a metal layer and a metal oxide layer are sequentially formed on the first main surface of the drive substrate 11 by, for example, a sputtering method, and then, the metal layer and the metal oxide layer are patterned by using, for example, a photolithography technique and an etching technique. With this arrangement, the first electrode layer 12 having the plurality of electrodes 12A and the cathode contact 15A are formed. Next, the inter-pixel insulating layer 13 is formed on the first main surface of the drive substrate 11 so as to cover the plurality of electrodes 12A by, for example, a chemical vapor deposition (CVD) method. Next, the opening 13A is formed in a portion of the inter-pixel insulating layer 13 located on the first main surface of each electrode 12A by, for example, the photolithography technique and a dry etching technique. An opening is similarly formed in the cathode contact 15A.

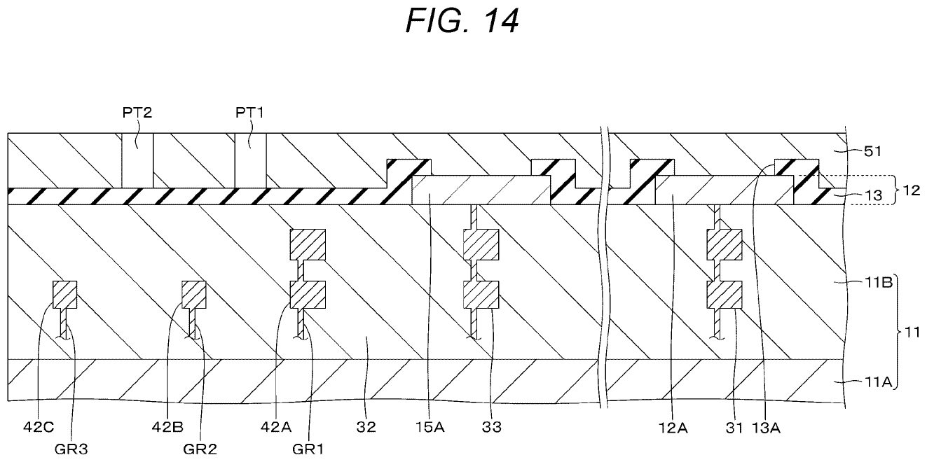

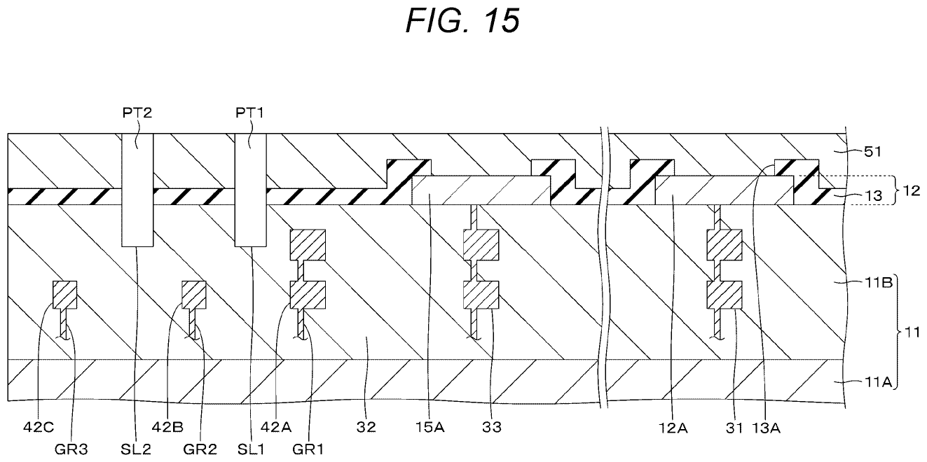

Next, as illustrated in FIG. 14, after a resist film 51 is formed, opening patterns PT1 and PT2 are formed by, for example, the photolithography technique. Next, as illustrated in FIG. 15, the first slit structure SL1 is formed at a position corresponding to the opening pattern PT1, and the second slit structure SL2 is formed at a position corresponding to the opening pattern PT2, by for example, the dry etching technique.

Next, after the resist film 51 is removed, the organic EL layer 14 is formed on the first main surface of the plurality of electrodes 12A and the first main surface of the inter-pixel insulating layer 13 by, for example, a vapor deposition method. Next, the second electrode layer 15 is formed on the first main surface of the organic EL layer 14 by, for example, the vapor deposition method or a sputtering method. With this arrangement, the plurality of light emitting elements 20 is formed on the first main surface of the drive substrate 11.

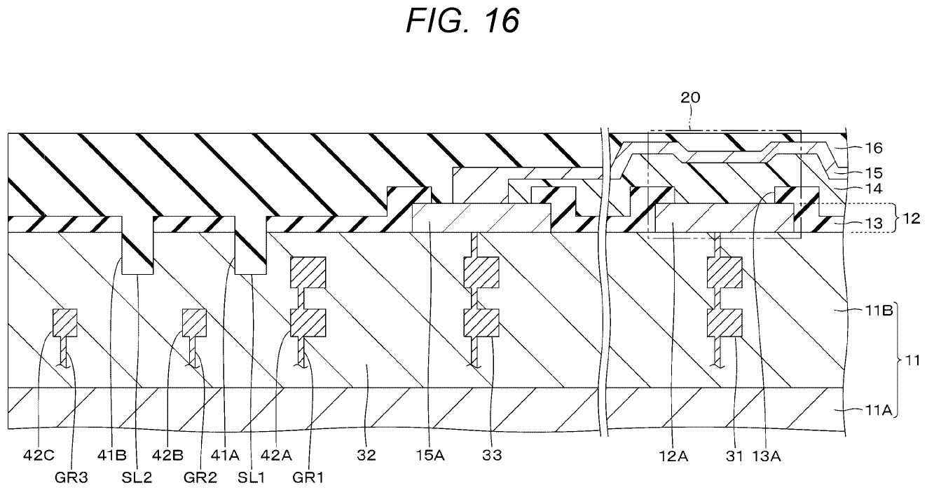

Next, as illustrated in FIG. 16, the protective layer 16 is formed on the first main surface of the second electrode layer 15 by, for example, the CVD method or the vapor deposition method. The first slit structure SL1 and the second slit structure SL2 are filled with the protective layer 16. Next, the color filter 17 is formed on the first main surface of the protective layer 16 by, for example, photolithography. Note that, in order to flatten a level difference of the protective layer 16 and a level difference due to a film thickness difference of the color filter 17 itself, a flattening layer may be formed on the upper side, the lower side, or both the upper and lower sides of the color filter 17. Next, the color filter 17 is covered with the filling resin layer 18 by using, for example, a one drop fill (ODF) method. Then, by disposing the sealant 25, and by applying heat to the sealant 25 or irradiating the sealant 25 with ultraviolet light and curing the sealant 25, the drive substrate 11 and the counter substrate 19 are bonded to each other. With this arrangement, the display device 1000 is sealed.

According to the above-described manufacturing method of the present embodiment, because the first slit structure SL1 and the second slit structure SL2 are formed before the organic EL layer 14 is formed, the organic EL layer 14 is not damaged at the time of forming the first slit structure SL1 and the second slit structure SL2. Furthermore, because the first slit structure SL1 and the second slit structure SL2 are filled with the protective layer 16, a step is not generated. Therefore, it is possible to prevent a situation in which a difference occurs in film thickness between the color filters 17 due to the step to cause an adverse effect such as quality deterioration of the display device 1.

### [Example of Resonator Structure Applied to Embodiment]

The pixel used in the display device according to the above-described present disclosure may have a configuration including a resonator structure that resonates light generated by the light emitting element. Hereinafter, the resonator structure will be described with reference to the drawings.

### (Resonator Structure: First Example)

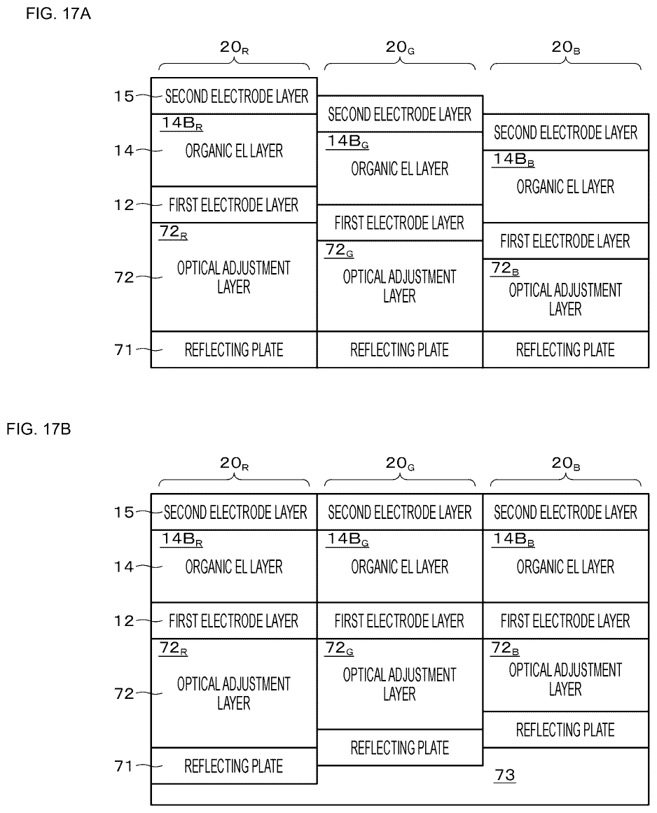

FIG. 17A is a schematic cross-sectional view for explaining a first example of the resonator structure. In the following description, in some cases, the light emitting elements 20 provided corresponding to the subpixels 100R, 100G, and 100B are referred to as light emitting elements 20R, 20G, and 20B, respectively. Furthermore, in some cases, portions of the organic EL layer 14 corresponding to the subpixels 100R, 100G, and 100B are referred to as organic EL layers 14R, 14G, and 14B, respectively.

In the first example, the first electrode layer 12 is formed to have a common film thickness in each light emitting element 20. This similarly applies to the second electrode layer 15.

A reflecting plate 71 is disposed below the first electrode layer 12 of the light emitting element 20 with an optical adjustment layer 72 interposed therebetween. A resonator structure that resonates light generated by the organic EL layer 14 is formed between the reflecting plate 71 and the second electrode layer 15. In the following description, the optical adjustment layers 72 provided corresponding to the subpixels 100R, 100G, and 100B are referred to as optical adjustment layers 72R, 72G, and 72B, respectively.

The reflecting plate 71 is formed to have a common film thickness in each light emitting element 20. The film thicknesses of the optical adjustment layers 72 are different according to a color to be displayed by the pixel. Because the optical adjustment layers 72R, 72G, and 72B have different film thicknesses, it is possible to set an optical distance at which optimum resonance occurs for a wavelength of light corresponding to a color to be displayed.

In the example illustrated in the drawing, the upper surfaces of the reflecting plates 71 in the light emitting elements 20R, 20G, and 20B are disposed in an aligning manner. As described above, because the film thicknesses of the optical adjustment layers 72 are different according to the color to be displayed by the pixel, positions of the upper surfaces of the second electrode layers 15 are different according to the types of the light emitting elements 20R, 20G, and 20B.

The reflecting plate 71 can include, for example, a metal such as aluminum (Al), silver (Ag), or copper (Cu), or an alloy containing these metals as main components.

The optical adjustment layer 72 can be configured by using an inorganic insulating material such as silicon nitride (SiNx), silicon oxide (SiOx), or silicon oxynitride (SiOxNy), or an organic resin material such as an acrylic resin or a polyimide resin. The optical adjustment layer 72 may be a single layer, or may be a laminated film of the plurality of materials of the above. Furthermore, the number of laminated layers may be different according to the types of the light emitting element 20.

The first electrode layer 12 can be formed by using a transparent conductive material such as indium tin oxide (ITO), indium zinc oxide (IZO), or zinc oxide (ZnO).

The second electrode layer 15 needs to function as a semi-transmissive reflecting film. The second electrode layer 15 can include magnesium (Mg) or silver (Ag), or a magnesium-silver alloy (MgAg) containing these as main components, or moreover, an alloy containing an alkali metal or an alkaline earth metal, or the like.

### (Resonator Structure: Second Example)

FIG. 17B is a schematic cross-sectional view for explaining a second example of the resonator structure.

Also in the second example, the first electrode layer 12 and the second electrode layer 15 are formed to have a common film thickness in each light emitting element 20.

Then, also in the second example, the reflecting plate 71 is disposed below the first electrode layer 12 of the light emitting element 20 with the optical adjustment layer 72 interposed therebetween. A resonator structure that resonates light generated by the organic EL layer 14 is formed between the reflecting plate 71 and the second electrode layer 15. Similarly to the first example, the reflecting plate 71 is formed with a common film thickness in each light emitting element 20, and the film thicknesses of the optical adjustment layers 72 are different according to the color to be displayed by the pixel.

In the first example illustrated in FIG. 17A, the upper surfaces of the reflecting plates 71 in the light emitting elements 20R, 20G, and 20B are disposed in an aligning manner, and the positions of the upper surface of the second electrode layers 15 are different according to the types of the light emitting elements 20R, 20G, and 20B.

On the other hand, in the second example illustrated in FIG. 17B, the upper surfaces of the second electrode layers 15 are disposed in an aligning manner between the light emitting elements 20R, 20G, and 20B. In order to align the upper surfaces of the second electrode layers 15, in the light emitting elements 20R, 20G, and 20B, the upper surfaces of the reflecting plates 71 are disposed in different positions according to the types of the light emitting elements 20R, 20G, and 20B. Therefore, the lower surfaces (in other words, the surface of a base 73 indicated by a reference numeral 73 in the drawing) of the reflecting plates 71 form a stair shape according to the types of the light emitting elements 20.

Materials and the like constituting the reflecting plate 71, the optical adjustment layer 72, the first electrode layer 12, and the second electrode layer 15 are similar to those described in the first example, and thus, the description thereof will be omitted.

### (Resonator Structure: Third Example)

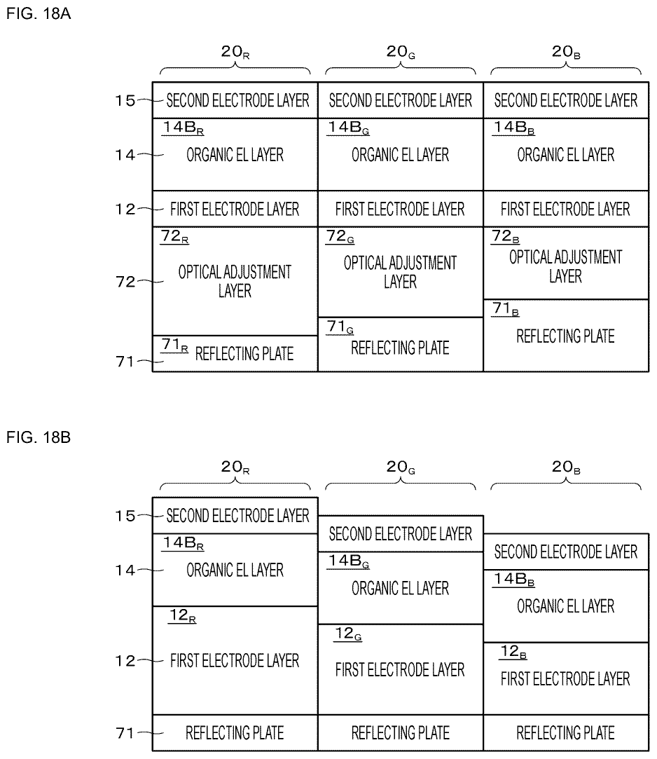

FIG. 18A is a schematic cross-sectional view for explaining a third example of the resonator structure. In the following description, in some cases, the reflecting plates 71 provided corresponding to the subpixels 100R, 100G, and 100B are referred to as reflecting plates 71R, 71G, and 71B, respectively.

Also in the third example, the first electrode layer 12 and the second electrode layer 15 are formed to have a common film thickness in each light emitting element 20.

In addition, also in the third example, the reflecting plate 71 is disposed below the first electrode layer 12 of the light emitting element 20 with the optical adjustment layer 72 interposed therebetween. The resonator structure that resonates light generated by the organic EL layer 14 is formed between the reflecting plate 71 and the second electrode layer 15. Similarly to the first and the second examples, the film thickness of the optical adjustment layers 72 are different according to the color to be displayed by the pixel. In addition, similarly to the second example, the upper surface of the second electrode layer 15 is disposed in an aligning manner between the light emitting elements 20R, 20G, and 20B.

In the second example illustrated in FIG. 17B, in order to align the upper surfaces of the second electrode layers 15, the lower surfaces of the reflecting plates 71 form a stair shape according to the types of the light emitting elements 20.

On the other hand, in the third example illustrated in FIG. 18A, the film thicknesses of the reflecting plates 71 are set to be different according to the types of the light emitting elements 20R, 20G, and 20B. More specifically, the film thicknesses are set such that the lower surfaces of the reflecting plates 71R, 71G, and 71B are aligned.

Materials and the like constituting the reflecting plate 71, the optical adjustment layer 72, the first electrode layer 12, and the second electrode layer 15 are similar to those described in the first example, and thus, the description thereof will be omitted.

### (Resonator Structure: Fourth Example)

FIG. 18B is a schematic cross-sectional view for explaining a fourth example of the resonator structure. In the following description, in some cases, the first electrode layers 12 provided corresponding to the subpixels 100R, 100G, and 100B are referred to as first electrode layers 12R, 12G, and 12B, respectively.

In the first example illustrated in FIG. 17A, the first electrode layer 12 and the second electrode layer 15 of each light emitting element 20 are formed to have a common film thickness. In addition, the reflecting plate 71 is disposed below the first electrode layer 12 of the light emitting element 20 with the optical adjustment layer 72 interposed therebetween.

On the other hand, in the fourth example illustrated in FIG. 18B, the optical adjustment layer 72 is omitted, and the film thicknesses of the first electrode layers 12 are set to be different according to the types of the light emitting elements 20R, 20G, and 20B.

The reflecting plate 71 is formed to have a common film thickness in each light emitting element 20. The film thicknesses of the first electrode layers 12 are different according to the color to be displayed by the pixel. By the first electrode layers 12R, 12G, and 12B having different film thicknesses, it is possible to set an optical distance for generating optimum resonance for the wavelength of light according to the color to be displayed.

Materials and the like constituting the reflecting plate 71, the optical adjustment layer 72, the first electrode layer 12, and the second electrode layer 15 are similar to those described in the first example, and thus, the description thereof will be omitted.

### (Resonator Structure: Fifth Example)

FIG. 19A is a schematic cross-sectional view for explaining a fifth example of the resonator structure.

In the first example illustrated in FIG. 17A, the first electrode layer 12 and the second electrode layer 15 are formed to have a common film thickness in each light emitting element 20. In addition, the reflecting plate 71 is disposed below the first electrode layer 12 of the light emitting element 20 with the optical adjustment layer 72 interposed therebetween.

On the other hand, in the fifth example illustrated in FIG. 19A, the optical adjustment layer 72 is omitted, and instead, an oxide film 74 is formed on the surface of the reflecting plate 71. The film thicknesses of the oxide films 74 are set to be different according to the types of the light emitting elements 20R, 20G, and 20B. In the following description, in some cases, the oxide films 74 provided corresponding to the subpixels 100R, 100G, and 100B are referred to as oxide films 74R, 74G, and 74B, respectively.

The film thicknesses of the oxide films 74 are different according to the color to be displayed by the pixel. By the oxide films 74R, 74G, and 74B having different film thicknesses, it is possible to set an optical distance for generating optimum resonance for the wavelength of light according to the color to be displayed.

The oxide film 74 is a film obtained by oxidizing the surfaces of the reflecting plate 71, and includes, for example, aluminum oxide, tantalum oxide, titanium oxide, magnesium oxide, zirconium oxide, or the like. The oxide film 74 functions as an insulating film for adjusting an optical path length (optical distance) between the reflecting plate 71 and the second electrode layer 15.

The oxide films 74 having different film thicknesses according to the types of the light emitting elements 20R, 20G, and 20B can be formed, for example, as follows.

First, an electrolytic solution is filled in a container, and a substrate on which the reflecting plate 71 is formed is immersed in the electrolytic solution. Furthermore, an electrode is disposed in a facing manner to the reflecting plate 71.

Then, a positive voltage is applied to the reflecting plate 71 with reference to the electrode, and the reflecting plate 71 is anodized. A film thickness of the oxide film obtained as a result of the anodization is proportional to a voltage value for the electrode. Therefore, anodization is performed in a state where a voltage corresponding to the types of the light emitting elements 20 is applied to each of the reflecting plates 71R, 71G, and 71B. As a result, the oxide films 74 having different film thicknesses can be collectively formed.

Materials and the like constituting the reflecting plate 71, the first electrode layer 12, and the second electrode layer 15 are similar to those described in the first example, and thus, the description thereof will be omitted.

### (Resonator Structure: Sixth Example)

FIG. 19B is a schematic cross-sectional view for explaining a sixth example of the resonator structure.

In the sixth example, the light emitting element 20 is configured by laminating the first electrode layer 12, the organic EL layer 14, and the second electrode layer 15. However, in the sixth example, the first electrode layer 12 is formed to have functions of both an electrode and a reflecting plate. The first electrode layer (-cum-reflecting plate) 12 includes a material having an optical constant selected according to the types of the light emitting elements 20R, 20G, and 20B. Because the phase shifts caused by the first electrode layers (-cum-reflecting plates) 12 are different from each other, it is possible to set an optical distance for generating optimum resonance for the wavelength of light according to the color to be displayed.

The first electrode layers (-cum-reflecting plates) 12 can include a single metal such as aluminum (Al), silver (Ag), gold (Au), or copper (Cu), or an alloy containing these metals as main components. For example, the first electrode layer (-cum-reflecting plate) 12R of the light emitting element 20R can include copper (Cu), and the first electrode layer (-cum-reflecting plate) 12G of the light emitting element 20G and the first electrode layer (-cum-reflecting plate) 12B of the light emitting element 20B can include aluminum.

Materials and the like constituting the second electrode layer 15 are similar to those described in the first example, and thus, the description thereof will be omitted.

### (Resonator Structure: Seventh Example)

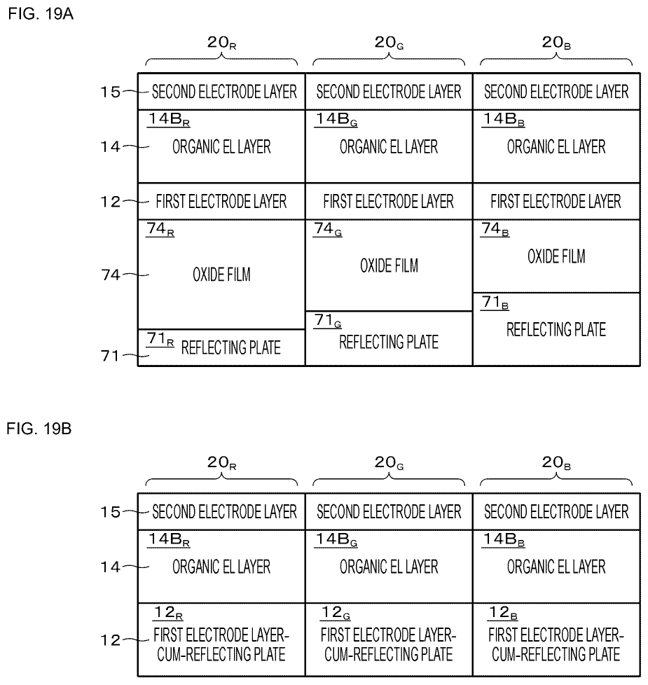

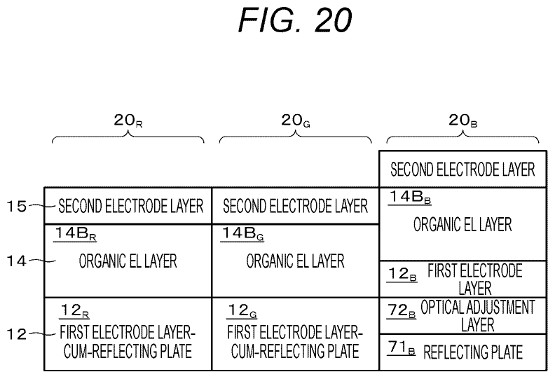

FIG. 20 is a schematic cross-sectional view for explaining a seventh example of the resonator structure.

The seventh example basically has a configuration in which the sixth example is applied to the light emitting elements 20R and 20G, and the first example is applied to the light emitting elements 20B. Also in this configuration, it is possible to set an optical distance that causes optimum resonance for a wavelength of light according to the color to be displayed.

The first electrode layers (-cum-reflecting plates) 12R and 12G used for the light emitting elements 20R and 20G can include a single metal such as aluminum (Al), silver (Ag), gold (Au), or copper (Cu), or an alloy containing these as main components.

Materials and the like constituting the reflecting plate 71B, the optical adjustment layer 72B, and the first electrode layer 12B used for the light emitting element 20B are similar to those described in the first example, and thus, the description thereof is omitted.

### [Relationship Among Normal Lines Passing Through Centers of Light Emitting Unit, Lens Member, and Wavelength Selection Unit]

The above-described display device 1000 may include a lens array (not illustrated) between the protective layer 16 and the color filter 17. The display device 1000 may further include a flattening layer (not illustrated) between the color filter 17 and the lens array.

The lens array includes a plurality of lenses. The lens may be an on chip microlens (OCL). The plurality of lenses is two-dimensionally arranged on the first main surface of the color filter 17 or the flattening layer in a prescribed arrangement pattern. One subpixel includes one or two lenses. The lens condenses the light emitted upward in the front direction. The lens has, for example, a convex curved surface protruding in the front direction. The convex curved surface has, for example, a dome shape. Here, the dome shape includes shapes such as a substantially parabolic shape, a substantially hemispherical shape, and a substantially semielliptical sphere.

The lens includes, for example, an inorganic material or a polymer resin transparent to visible light. The inorganic material includes, for example, silicon oxide (SiOx). The polymer resin includes, for example, an ultraviolet curable resin.

Hereinafter, the relationship among a normal line LN passing through the center of a light emitting unit, a normal line LN′ passing through the center of a lens member, and a normal line LN″ passing through the center of a wavelength selection unit is described. Here, a light emitting unit 81 described below is, for example, the above-described light emitting element 20. Furthermore, a lens member 83 described below is, for example, the lens of the lens array. Furthermore, a wavelength selection unit 82 described below is, for example, the color filter 17.

Note that the size of the wavelength selection unit may be changed as appropriate in accordance with light emitted from the light emitting unit, or, in a case where a light absorbing unit (for example, a black matrix unit) is provided between the wavelength selection units of the adjacent light emitting units, the size of the light absorbing unit may be changed as appropriate in accordance with light emitted from the light emitting unit. Furthermore, the size of the wavelength selection unit may be changed as appropriate in accordance with a distance (offset amount) d0 between the normal line passing through the center of the light emitting unit and the normal line passing through the center of the wavelength selection unit. The planar shape of the wavelength selection unit may be the same as, similar to, or different from the planar shape of the lens member.

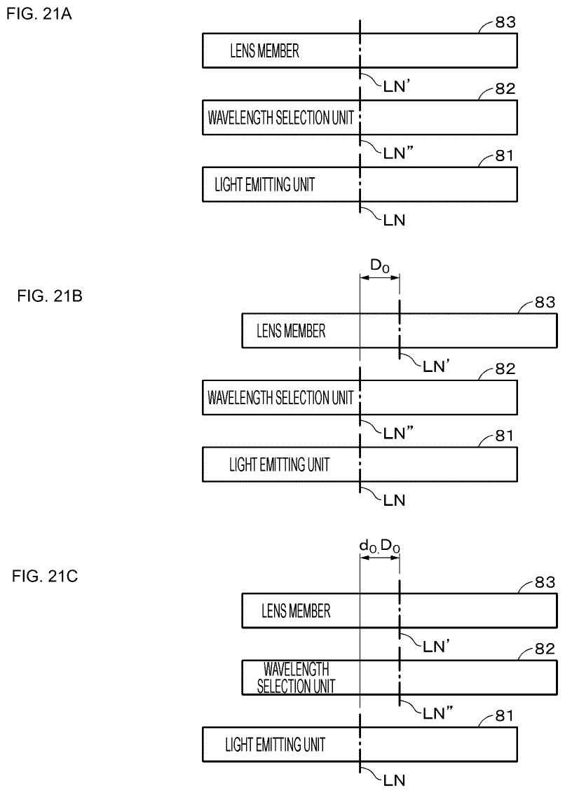

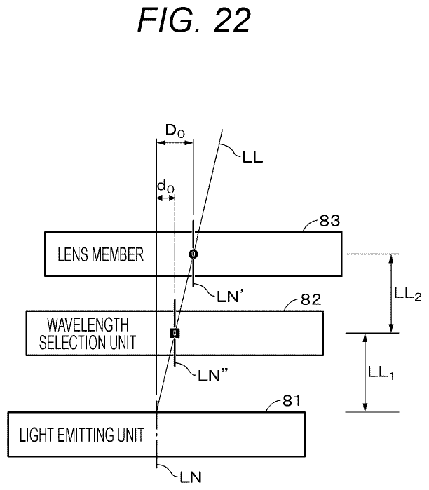

Hereinafter, with reference to FIGS. 21A, 21B, 21C, and 22, a relationship among the normal lines each passing through the center of each unit in a case where the light emitting unit 81, the wavelength selection unit 82, and the lens member 83 are disposed in this order will be described.

As illustrated in FIG. 21A, the normal line LN passing through the center of the light emitting unit 81, the normal line LN″ passing through the center of the wavelength selection unit 82, and the normal line LN′ passing through the center of the lens member 83 may coincide with each other. That is, D0=0 and d0=0 may be satisfied. Here, D0 represents a distance (offset amount) between the normal line LN passing through the center of the light emitting unit 81 and the normal line LN′ passing through the center of the lens member 83, and d0 represents a distance (offset amount) between the normal line LN passing through the center of the light emitting unit 81 and the normal line LN″ passing through the center of the wavelength selection unit 82.

As illustrated in FIG. 21B, it may be configured that the normal line LN passing through the center of the light emitting unit 81 and the normal line LN″ passing through the center of the wavelength selection unit 82 coincide with each other, but the normal line LN extending through the center of the light emitting unit 81 and the normal line LN″ passing through the center of the wavelength selection unit 82 do not coincide with the normal line LN′ passing through the center of the lens member 83. That is, D0>0 and d0=0 may be satisfied.

As illustrated in FIG. 21C, it may be configured that the normal line LN passing through the center of the light emitting unit 81 does not coincide with the normal line LN″ passing through the center of the wavelength selection unit 82 and the normal line LN′ passing through the center of the lens member 83, and the normal line LN″ passing through the center of the wavelength selection unit 82 coincides with the normal line LN′ passing through the center of the lens member 83. That is, D0>0, d0>0, and D0=d0 may be satisfied.

As illustrated in FIG. 22, it may be configured that the normal line LN passing through the center of the light emitting unit 81, the normal line LN″ passing through the center of the wavelength selection unit 82, and the normal line LN′ passing through the center of the lens member 83 do not coincide with each other. That is, D0>0, d0>0, and D0≠d0 may be satisfied. Here, the center of the wavelength selection unit 82 (position indicated by a black square in FIG. 22) is preferably located on a straight line LL connecting the center of the light emitting unit 81 and the center of the lens member 83 (position indicated by a black circle in FIG. 22). Specifically, assuming that a distance in the thickness direction (vertical direction in FIG. 22) between the center of the light emitting unit 81 and the center of the wavelength selection unit 82 is LL1, and that a distance in the thickness direction between the center of the wavelength selection unit 82 and the center of the lens member 83 is LL2, it is preferable that

$$D 0 > d 0 > 0$$

is satisfied, and with manufacturing variations being taken into consideration,

$$d0 : D 0 = LL 1 : ( LL 1 + LL 2 )$$

is satisfied.

Here, the thickness direction indicates the thickness direction of the light emitting unit 81, the wavelength selection unit 82, and the lens member 83.

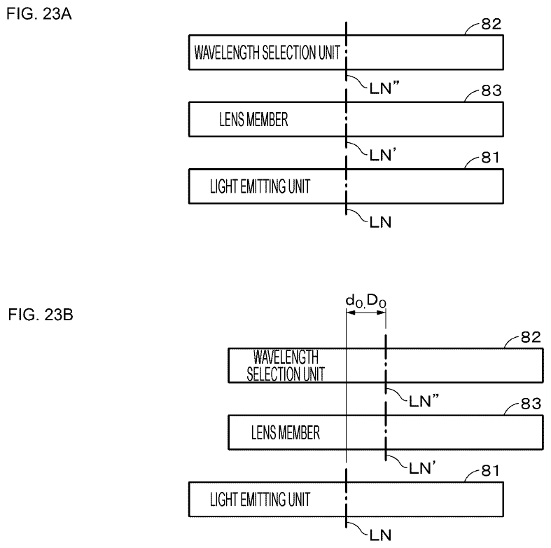

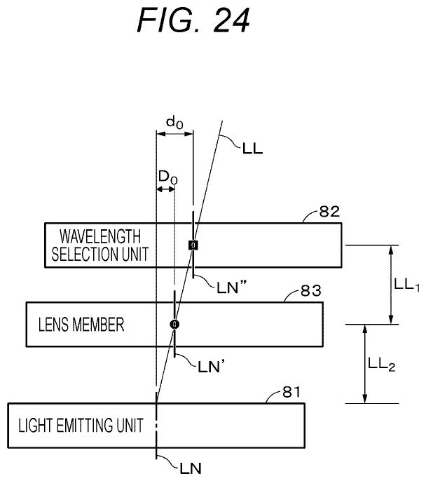

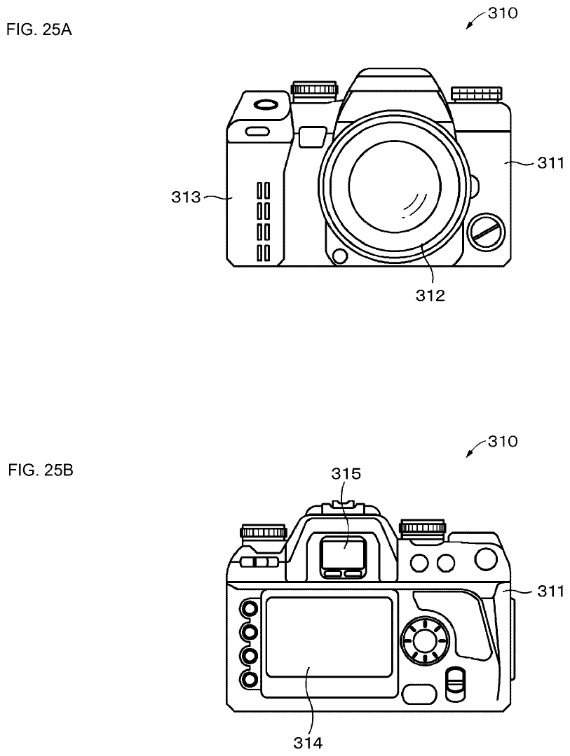

Hereinafter, with reference to FIGS. 23A, 23B, and 24, a relationship among the normal lines each passing through the center of each unit in a case where the light emitting unit 81, the lens member 83, and the wavelength selection unit 82 are disposed in this order will be described.

As illustrated in FIG. 23A, it may be configured that the normal line LN passing through the center of the light emitting unit 81, the normal line LN″ passing through the center of the wavelength selection unit 82, and the normal line LN′ passing through the center of the lens member 83 coincide with each other. That is, D0>0 and d0=0 may be satisfied.

As illustrated in FIG. 23B, it may be configured that the normal line LN passing through the center of the light emitting unit 81 does not coincide with the normal line LN″ passing through the center of the wavelength selection unit 82 and the normal line LN′ passing through the center of the lens member 83, and the normal line LN″ passing through the center of the wavelength selection unit 82 coincides with the normal line LN′ passing through the center of the lens member 83. That is, D0>0, d0>0, and D0=d0 may be satisfied.

As illustrated in FIG. 24, it may be configured that the normal line LN passing through the center of the light emitting unit 81, the normal line LN″ passing through the center of the wavelength selection unit 82, and the normal line LN′ passing through the center of the lens member 83 do not coincide with each other. Here, the center of the lens member 83 (the position indicated by a black circle in FIG. 24) is preferably located on a straight line LL connecting the center of the light emitting unit 81 and the center of the wavelength selection unit 82 (position indicated by a black square in FIG. 24). Specifically, assuming that a distance in the thickness direction (vertical direction in FIG. 24) between the center of the light emitting unit 81 and the center of the lens member 83 is LL2, and that a distance in the thickness direction between the center of the lens member 83 and the center of the wavelength selection unit 82 is LL1, it is preferable that

$$d 0 > D 0 > 0$$

is satisfied, and, with manufacturing variations being taken into consideration,

$$D 0 : d 0 = LL 2 : ( LL 1 + LL 2 )$$

is satisfied.

Here, the thickness direction indicates the thickness direction of the light emitting unit 81, the wavelength selection unit 82, and the lens member 83.

### APPLICATION EXAMPLES

### Electronic Apparatus

The display device 1000 according to the embodiment described above may be provided in various electronic apparatuses. The display device 1000 and the like are suitable especially for an electronic viewfinder of a video camera or a single-lens reflex camera, a head-mounted display, or the like that requires high resolution and is used near the eyes in an enlarged manner.

### Specific Example 1

FIGS. 25A and 25B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip part 313 to be held by a photographer on the front left side.

A monitor 314 is provided at a position shifted to the left side from the center of the back surface of the camera main body 311. An electronic viewfinder (eyepiece window) 315 is provided above the monitor 314. By looking through the electronic viewfinder 315, the photographer can visually recognize an optical image of a subject guided from the imaging lens unit 312, and determine a picture composition. The electronic viewfinder 315 includes the display device 1000 described above.

### Specific Example 2

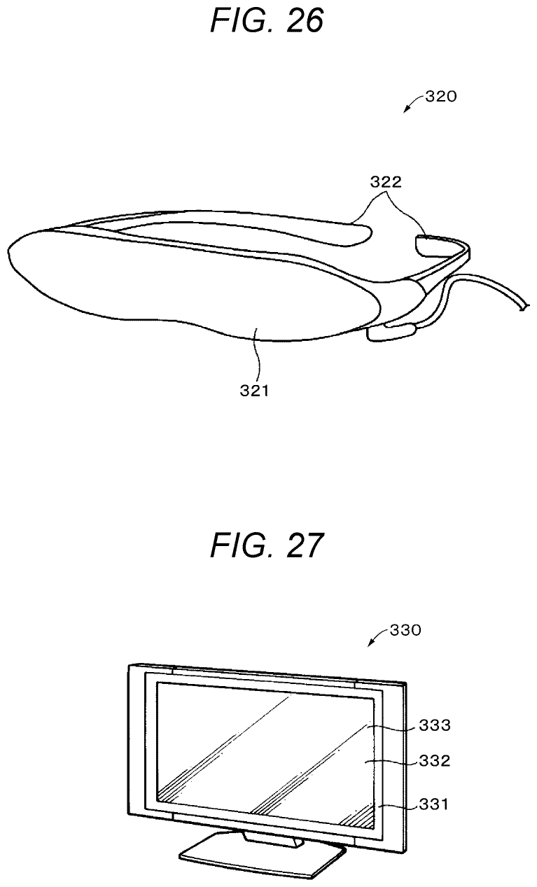

FIG. 26 illustrates an example of an external appearance of a head-mounted display 320. The head-mounted display 320 includes, for example, ear hooking parts 322 for a user to wear the head-mounted display 320 on the head, on both sides of a display unit 321 having a shape of eyeglasses. The display unit 321 includes the display device 1000 described above.

### Specific Example 3

FIG. 27 illustrates an example of an external appearance of a television device 330. The television device 330 includes, for example, a video display screen unit 331 including a front panel 332 and a filter glass 333, and the video display screen unit 331 includes the display device 1000 described above.

### Specific Example 4

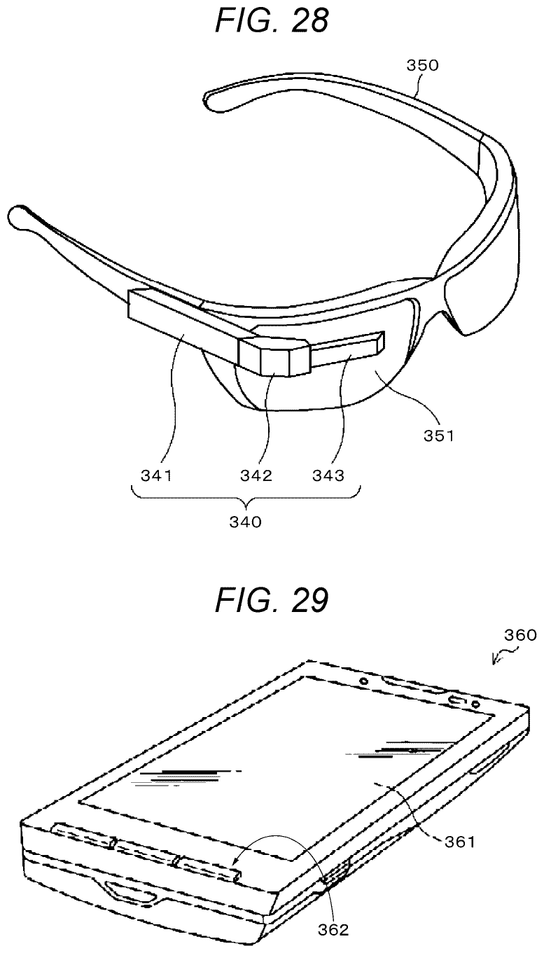

FIG. 28 illustrates an example of an appearance of a see-through head-mounted display 340. The see-through head-mounted display 340 includes a main body 341, an arm 342, and a lens barrel 343.

The main body 341 is connected to the arm 342 and eyeglasses 350. Specifically, the end of the main body 341 in the long side direction is coupled to the arm 342, and one side of the side surface of the main body 341 is coupled to the eyeglasses 350 via a connecting member. Note that the main body 341 may be mounted directly on the head of the human body.

The main body 341 includes a control board for controlling operations of the see-through head-mounted display 340, and a display unit. The arm 342 connects the main body 341 and the lens barrel 343, and supports the lens barrel 343. Specifically, the arm 342 is coupled to each of the end of the main body 341 and the end of the lens barrel 343, and fixes the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes the display device 1000 described above.

### Specific Example 5

FIG. 29 illustrates an example of an external appearance of a smartphone 360. The smartphone 360 includes a display unit 361 that displays various types of information, an operation unit 362 formed with buttons for receiving operation inputs from the user, and the like. The display unit 361 includes the display device 1000 described above.

### Specific Example 6

The display device 101 and the like described above may be included in a vehicle or in various displays.

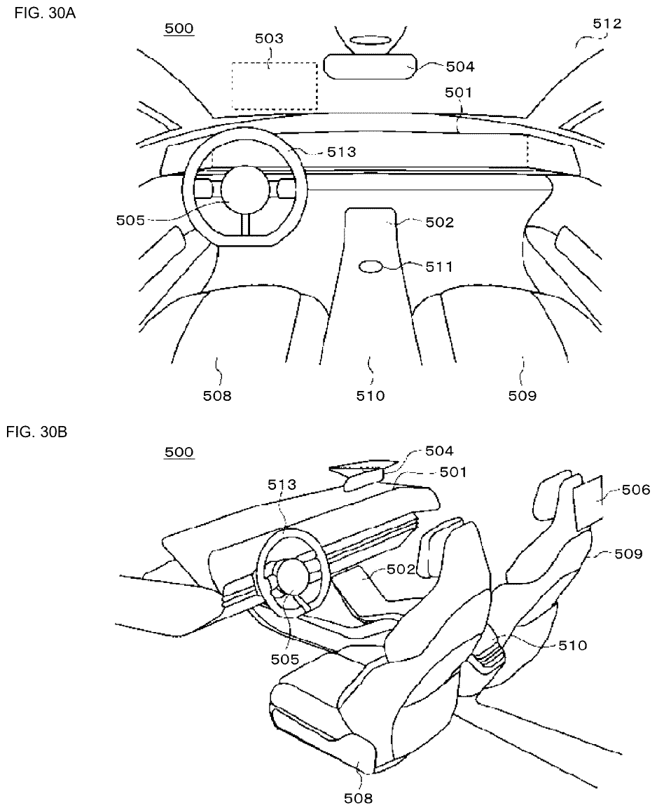

FIGS. 30A and 30B are views illustrating an example of an internal configuration of a vehicle 500 provided with various displays. Specifically, FIG. 30A is a view illustrating an example of an internal state of the vehicle 500 as viewed from the rear to the front of the vehicle 500, and FIG. 30B is a view illustrating an example of an internal state of the vehicle 500 as viewed from the oblique rear to the oblique front of the vehicle 500.

The vehicle 500 includes a center display 501, a console display 502, a head-up display 503, a digital rearview mirror 504, a steering wheel display 505, and a rear entertainment display 506. At least one of these displays includes the display device 1000 described above. For example, all of these displays may include the display device 1000 described above.

The center display 501 is disposed on the dashboard at a location facing a driver seat 508 and a passenger seat 509. FIGS. 30A and 30B illustrate an example of the center display 501 having a horizontally long shape extending from the driver seat 508 side to the passenger seat 509 side, but the screen size and the arrangement place of the center display 501 are optional. The center display 501 can display information sensed by various sensors. As a specific example, the center display 501 can display an image captured by an image sensor, a distance image of an obstacle in front of or on a side of the vehicle 500, the distance being measured by a time-of-flight (ToF) sensor, a body temperature of a passenger detected by an infrared sensor, and the like. The center display 501 can be used to display, for example, at least one of safety-related information, operation-related information, a life log, health-related information, authentication/identification-related information, and entertainment-related information.

The safety-related information is information such as doze sensing, looking-away sensing, sensing of mischief of a child riding together, and presence or absence of wearing of a seat belt, sensing of leaving of an occupant, and is information sensed by a sensor disposed, for example, to overlap with the back surface side of the center display 501. The operation-related information is information obtained by using the sensor to detect gestures related to operations by the occupant. Gestures to be sensed may include operations of various types of equipment in the vehicle 500. For example, operations of air conditioning equipment, a navigation device, an audiovisual (AV) device, a lighting device, and the like are detected. The life log include life logs of all the occupants. For example, the lifelogs include an action record of each occupant in the vehicle. By acquiring and storing the life log, a condition of the occupant can be confirmed at a time of an accident. The health-related information senses the body temperature of the occupant, by using a sensor such as a temperature sensor, and estimates the health condition of the occupant on the basis of the sensed body temperature. Alternatively, the face of the occupant may be imaged by using an image sensor, and the health condition of the occupant may be estimated from the imaged facial expression. Moreover, a conversation may be made with the occupant in automatic voice, and the health condition of the occupant may be estimated on the basis of the contents of a response from the occupant. The authentication/identification-related information includes information on a keyless entry function of performing face authentication by using a sensor, and a function of automatically adjusting a seat height and position through face identification. The entertainment-related information includes information on a function of detecting, with a sensor, operation information about an audio/visual (AV) device being used by the occupant, and a function of recognizing the face of the occupant with the sensor and providing content suitable for the occupant through the AV device.

The console display 502 can be used, for example, to display lifelog information. The console display 502 is disposed near a shift lever 511 of a center console 510 between the driver seat 508 and the passenger seat 509. The console display 502 can also display information detected by various sensors. Furthermore, the console display 502 may display an image of the surroundings of the vehicle captured with an image sensor, or may display a distance image of an obstacle present in the surroundings of the vehicle.

The head-up display 503 is virtually displayed behind a windshield 512 in front of the driver seat 508. The head-up display 503 can be used to display, for example, at least one of the safety-related information, the operation-related information, the life log, the health-related information, the authentication/identification-related information, and the entertainment-related information. Because the head-up display 503 is virtually disposed in front of the driver seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but can also display the state of the occupant in the rear seat, and thus, can be used to display, for example, the life log information, by disposing a sensor on the back surface side of the digital rearview mirror 504 in an overlapping manner.

The steering wheel display 505 is disposed near the center of a steering wheel 513 of the vehicle 500. The steering wheel display 505 can be used to display, for example, at least one of the safety-related information, the operation-related information, the life log, the health-related information, the authentication/identification-related information, and the entertainment-related information. In particular, because the steering wheel display 505 is located close to the hands of the driver, the steering wheel display 505 is suitable for displaying the life log information such as the body temperature of the driver, or for displaying information regarding operations of the AV device, the air conditioning equipment, or the like.

The rear entertainment display 506 is attached to the back surface side of the driver seat 508 or the passenger seat 509, and is for the occupant in the rear seat to enjoy viewing/listening. The rear entertainment display 506 can be used to display, for example, at least one of the safety-related information, the operation-related information, the life log, the health-related information, the authentication/identification-related information, and the entertainment-related information. In particular, because the rear entertainment display 506 is located in front of the occupant in the rear seat, information related to the occupant in the rear seat is displayed on the rear entertainment display 506. For example, information regarding the operation of the AV device or the air conditioning equipment may be displayed, or a result of measurement of the body temperature or the like of the occupant in the rear seat with a temperature sensor may be displayed on the display.

It may be configured that a sensor is disposed on the back surface side of the display device 1000 in an overlapping manner to allow the distance to an object present in the surroundings to be measured. Optical distance measurement methods are roughly classified into a passive type and an active type. By the method of the passive type, distance measurement is performed by receiving light from an object, without projecting light from a sensor to the object. The method of the passive type includes a lens focus method, a stereo method, a monocular vision method, and the like. By the method of the active type, distance measurement is performed by projecting light onto an object, and receiving reflected light from the object with a sensor to measure the distance. The method of the active type includes an optical radar method, an active stereo method, an illuminance difference stereo method, a moire topography method, and an interference method. Any of the display device 101 described above and the like can be used in distance measurement by any of these methods. By using the sensor disposed to overlap the back surface side of the display device 1000 described above, the above-described passive or active distance measurement can be performed.

### <Modifications>

Although the embodiment of the present disclosure has been specifically described above, the content of the present disclosure is not limited to the above-described embodiment, and various modifications based on the technical idea of the present disclosure are possible. Hereinafter, a plurality of modifications will be described.

### [Modification 1]

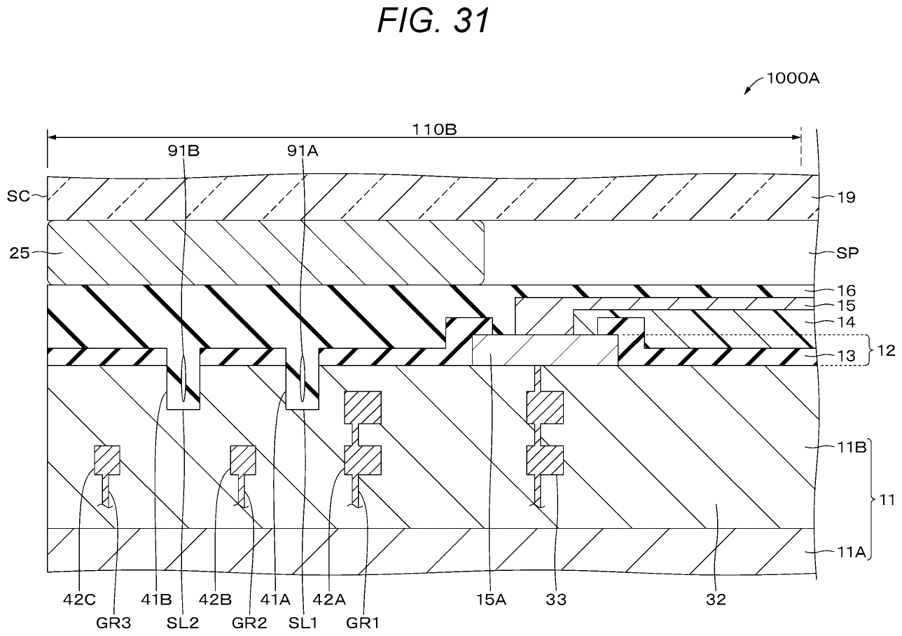

FIG. 31 is a view illustrating a cross-sectional configuration example of a display device (display device 1000A) according to the present modification. The present modification is different from the embodiment in that the protective layer 16 is filled in a manner that a cavity is formed in each of the first slit structure SL1 and the second slit structure SL2.

For example, as illustrated in FIG. 31, a cavity 91A is formed in the protective layer 16 filled in the first slit structure SL1, and a cavity 91B is formed in the protective layer 16 filled in the second slit structure SL2. The cavity 91A and the cavity 91B can be formed by appropriately adjusting film formation conditions of the protective layer 16, an aspect ratio of the first slit structure SL1 and the second slit structure SL2 in cross-sectional view, and the like.

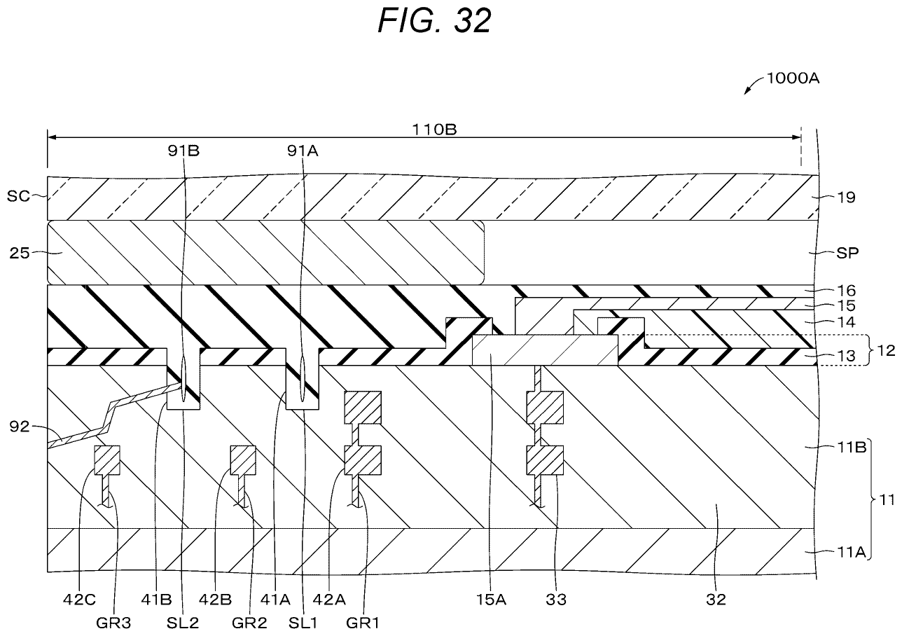

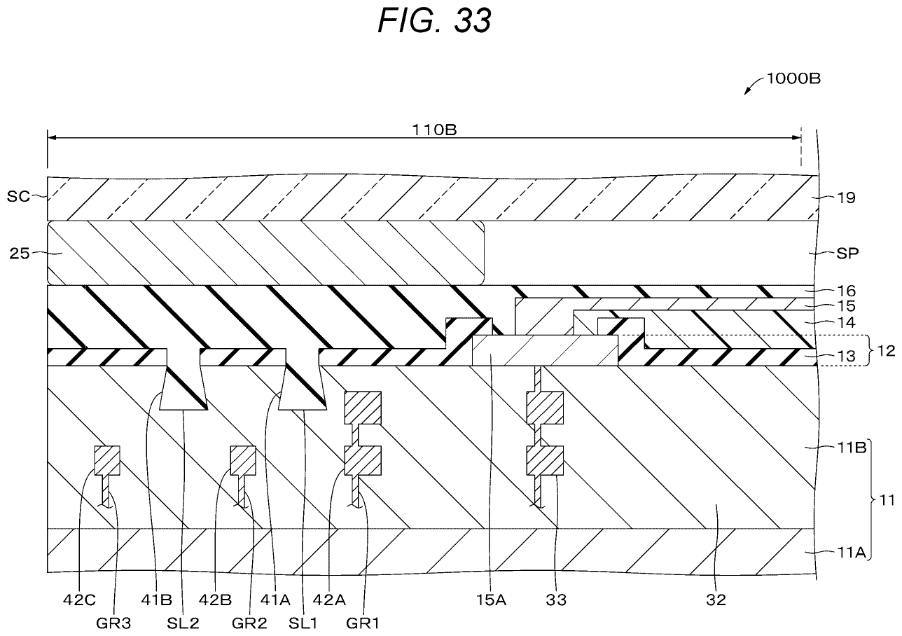

By providing the cavity 91A and the cavity 91B, progress of the chipping can be effectively suppressed. As schematically illustrated in FIG. 32, even in a case where a chipping 92 advances inside the display device 1000A on the upper part of the interlayer insulating layer 32 and further progresses, for example, the protective layer 16 inside the second slit structure SL2, the progress of the chipping 92 can be suppressed by the cavity 91B. Furthermore, even in a case where the chipping 92 has progressed through the protective layer 16 inside the first slit structure SL1, the progress of the chipping 92 can be suppressed by the cavity 91A. Note that the cavity 91A may extend to the outside of the first slit structure SL1. This similarly applies to the cavity 91B.

### [Modification 2]

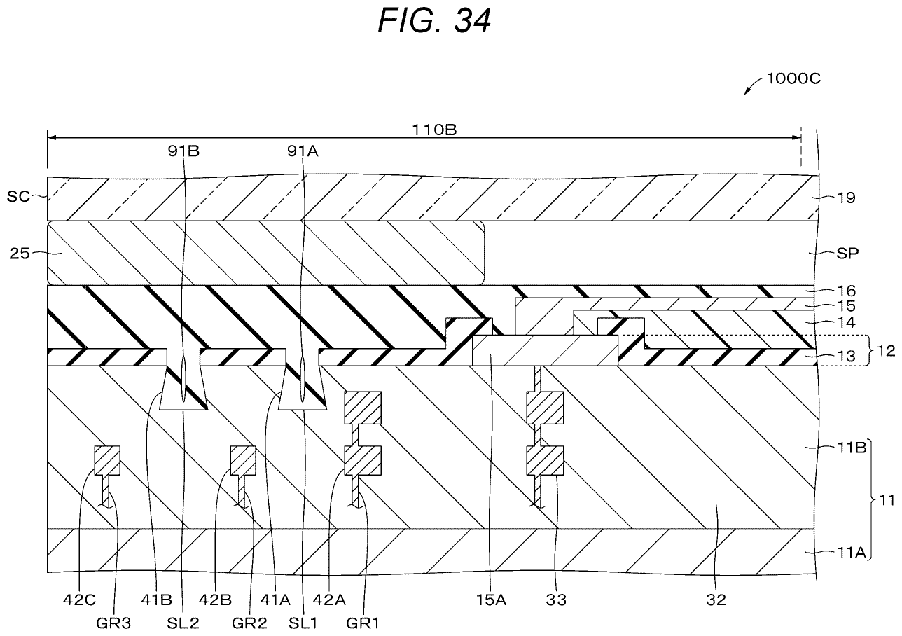

FIG. 33 is a view illustrating a cross-sectional configuration example of a display device (display device 1000B) according to the present modification. In the present modification, the shapes of the first slit structure SL1 and the second slit structure SL2 are different from those of the embodiment. In the present modification, as illustrated in FIG. 33, the shapes of the first slit structure SL1 and the second slit structure SL2 are reversely tapered. The reversely tapered shape means a shape in which the widths (lengths in the horizontal direction in FIG. 33) of the first slit structure SL1 and the second slit structure SL2 gradually increase toward the inside (second main surface side) of the interlayer insulating layer 32. Because the widths of the first slit structure SL1 and the second slit structure SL2 can be increased, the progress of the chipping can be effectively suppressed.

### [Modification 3]

FIG. 34 is a view illustrating a cross-sectional configuration example of a display device (display device 1000C) according to the present modification. The present modification is a modification obtained by combining Modification 1 and Modification 2 described above. In the present modification, as illustrated in FIG. 34, the shapes of the first slit structure SL1 and the second slit structure SL2 are reversely tapered. Moreover, the cavity 91A is formed in the protective layer 16 filled in the first slit structure SL1, and the cavity 91B is formed in the protective layer 16 filled in the second slit structure SL2.

Also with the configuration according to the present modification, the progress of the chipping can be effectively suppressed similarly to Modification 1 and Modification 2. Furthermore, the first main surface side (upper side in FIG. 34) of the first slit structure SL1 and the second slit structure SL2 is smaller in width than the second main surface side (lower side in FIG. 34). With this arrangement, the distal ends of the first slit structure SL1 and the second slit structure SL2 on the first main surface side are easily closed at the time of forming the protective layer 16, and the cavity 91A can be easily formed in the first slit structure SL1 and the cavity 91B can be easily formed in the second slit structure SL2.

### [Modification 4]

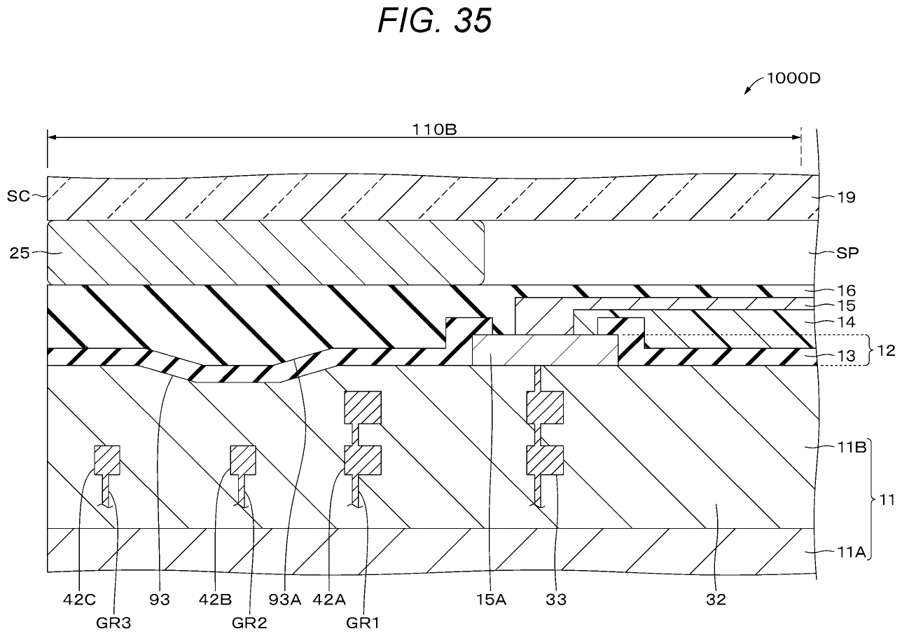

FIG. 35 is a view illustrating a cross-sectional configuration example of a display device (display device 1000D) according to the present modification. Unlike the display device 1000 according to the embodiment, the display device 1000D does not have the first slit structure SL1 and the second slit structure SL2. Furthermore, the display device 1000D includes a recess 93 formed on the first main surface side of the interlayer insulating layer 32. In the present modification, the recess 93 is constituted of the recess formed on the first main surface of the interlayer insulating layer 32 and the inter-pixel insulating layer 13 laminated on this recess. The recess 93 has a tapered shape, that is, a shape widening toward the first main surface side of the interlayer insulating layer 32.

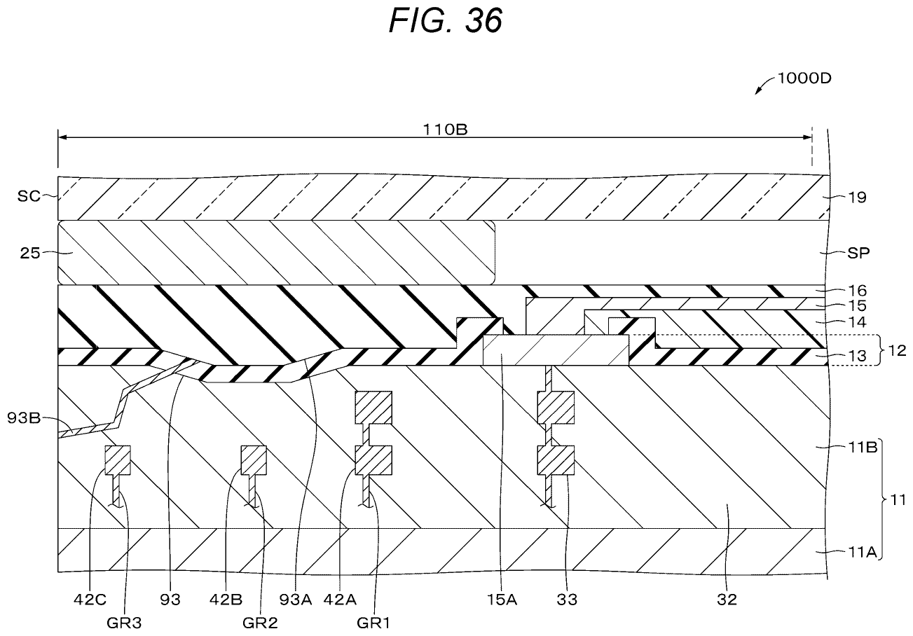

A first interface according to the present modification is includes a boundary 93A between the recess 93 and the protective layer 16. According to the present modification, as schematically illustrated in FIG. 36, the progress of a chipping 93B can be suppressed by the boundary 93A. Furthermore, because the recess 93 has a tapered shape, the color filter 17 can be prevented from being retained in the vicinity of the step which causes application unevenness and change the film thickness.

Note that the inter-pixel insulating layer 13 may not be provided, and in this case, the first interface is constituted of a boundary between the recess formed on the first main surface of the interlayer insulating layer 32 and the protective layer 16 laminated on the recess. Furthermore, a cavity may be formed between the recess 93 and the protective layer 16, or a configuration in which the protective layer 16 is laminated on the recess 93 and is in contact with the first main surface of the protective layer 16 may be the cavity. Also with this configuration, the progress of the chipping can be suppressed.

### [Modification 5]

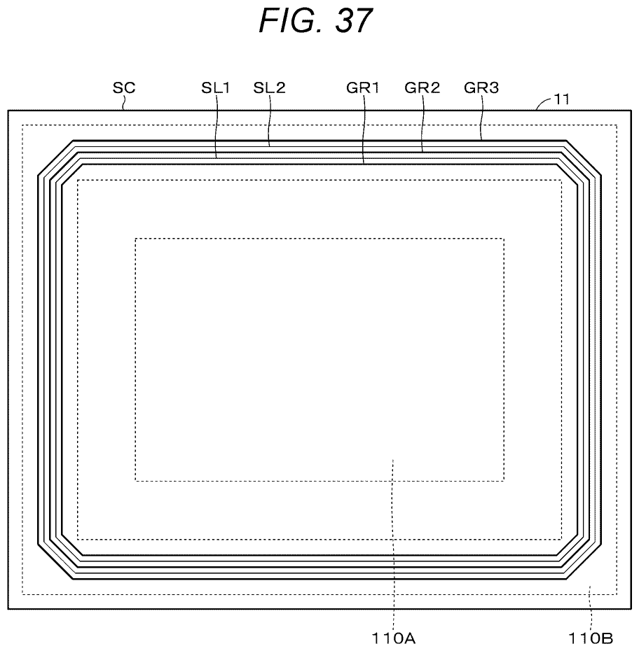

As illustrated in FIG. 37, the first slit structure SL1 and the second slit structure SL2, the first guard ring GR1, the second guard ring GR2, and the third guard ring GR3 may have a frame shape in which portions near the corners are cut in plan view.

### [Modification 6]

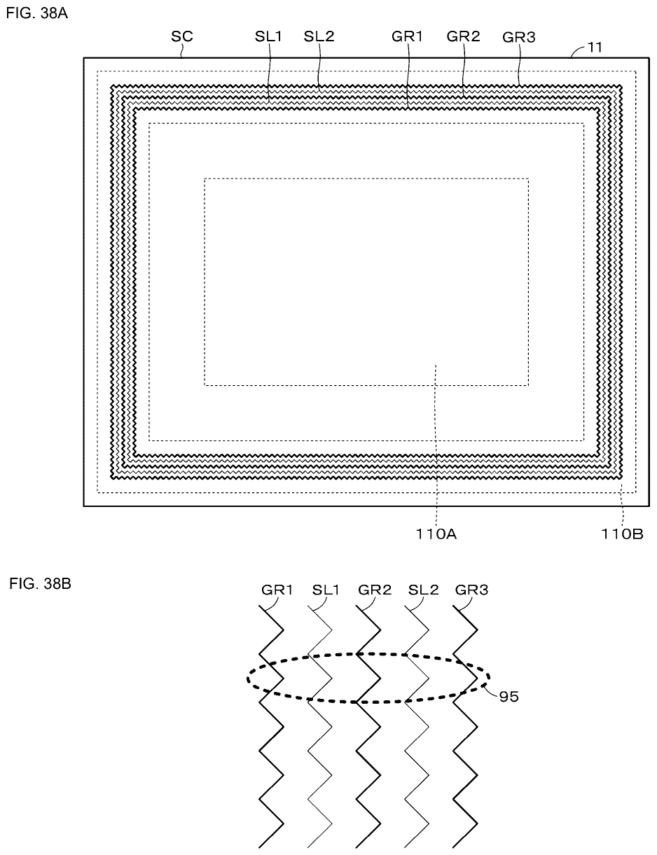

As illustrated in FIG. 38A, the first slit structure SL1 and the second slit structure SL2, the first guard ring GR1, the second guard ring GR2, and the third guard ring GR3 may not be straight lines in plan view, but may be zigzag in which irregularities are formed inside and outside the peripheral region 110B. With this arrangement, as illustrated in FIG. 38B, a stress concentration part 95 can be formed at a portion where the zigzag-shaped crest portions overlap. The stress concentration part 95 is a portion where chipping easily progresses. The progress of the chipping can be effectively suppressed by increasing, for example, the number of wiring layers of the guard ring in the stress concentration part 95.

### [Other Modifications]

In the above-described embodiment, there may be no inter-pixel insulating layer in the peripheral region. Furthermore, the slit structure and the guard ring may not be continuous as illustrated in FIG. 7, and may be partially divided. Furthermore, in a case where a plurality of slit structures are provided, the shapes of the individual slit structures may be different. Furthermore, the guard ring may be a structure not intended to prevent moisture infiltration. The configuration related to the guard ring may be a slit structure instead of the wiring structure. The slit structure and the guard ring may each be provided in a single piece, but it is preferable to have a configuration in which a plurality of slit structures and guard rings are provided from the viewpoint of suppressing the progress of the chipping. Furthermore, the present disclosure is also applicable to a display device using a light emitting diode (LED) element. Furthermore, the above-described application examples can also be applied to the display device according to the modification.

The configurations, methods, steps, shapes, materials, numerical values, and the like described in the embodiment and the modifications are merely examples, and configurations, methods, steps, shapes, materials, numerical values, and the like different from those described above may be used as necessary. Furthermore, the materials exemplified in the embodiment and the modifications can be used alone or in combination of two or more unless otherwise specified.

Furthermore, the present disclosure may also employ the following configurations.

(1)

A display device including:
a drive substrate having a pixel region in which a plurality of pixels is formed and a peripheral region provided between the pixel region and an outer edge, in which
the drive substrate is provided with a first interface on a first main surface side of the drive substrate in the peripheral region, and is provided with a second interface on a second main surface side of the drive substrate in the peripheral region, and
the pixels each include a first electrode, a second electrode disposed to face the first electrode, and an organic layer provided between the first electrode and the second electrode and including a light emitting layer.
   (2)

The display device according to (1), in which
the drive substrate includes a base material and a drive circuit layer laminated on the base material and including an interlayer insulating layer, and
the first interface and the second interface are provided at least on the interlayer insulating layer.
   (3)

The display device according to (2), in which
the first interface includes a first recess provided on the first main surface side of the interlayer insulating layer.
   (4)

The display device according to (3), further including
a protective layer laminated on the second electrode, in which
the first recess is filled with the protective layer.
   (5)

The display device according to (4), in which
the first recess is filled with the protective layer while a cavity is formed in the protective layer.
   (6)

The display device according to (5), in which
the first recess has a shape widening toward an inside of the interlayer insulating layer.
   (7)

The display device according to (2), further including:
a protective layer laminated on the second electrode; and
a first recess provided on the first main surface side of the interlayer insulating layer, in which
the first interface includes a boundary between the protective layer and the first recess.
   (8)

The display device according to (7), in which
the first recess has a shape widening toward the first main surface side.
   (9)

The display device according to any one of (1) to (8), in which
the second interface includes a wiring structure provided in the interlayer insulating layer.
   (10)

The display device according to any one of (1) to (9), further including
the first interface and the second interface each provided in plural numbers.
   (11)

The display device according to any one of (1) to (10), in which
the first interface includes an interface of the same type of material or different types of material.
   (12)

The display device according to any one of (1) to (11), in which
the second interface includes an interface of the same type of material or different types of material.
   (13)

The display device according to any one of (1) to (12), in which,
in the peripheral region, the first interface and the second interface have a frame shape.
   (14)

The display device according to any one of (1) to (12), in which,
in the peripheral region, the first interface and the second interface have an uneven shape on the inside and the outside of the peripheral region.
   (15)

The display device according to any one of (1) to (14), in which
the peripheral region is provided in a region near a scribe line.
   (16)

An electronic apparatus including the display device according to any one of (1) to (15).

### REFERENCE SIGNS LIST

11 Drive substrate
11A Base material
11B Drive circuit layer
12 First electrode layer
14 Organic EL layer
15 Second electrode layer
16 Protective layer
32 Interlayer insulating layer
41A, 41B, 42A, 42B, 42C Interface
91A, 91B Cavity
110A Display region
110B Peripheral region
1000 Display device
SL1 First slit structure
SL2 Second slit structure
SC Scribe line
GR1 First guard ring
GR2 Second guard ring
GR3 Third guard ring

1. A display device comprising:
a drive substrate having a pixel region in which a plurality of pixels is formed and a peripheral region provided between the pixel region and an outer edge, wherein
the drive substrate is provided with a first interface on a first main surface side of the drive substrate in the peripheral region, and is provided with a second interface on a second main surface side of the drive substrate in the peripheral region, and
the pixels each include a first electrode, a second electrode disposed to face the first electrode, and an organic layer provided between the first electrode and the second electrode and including a light emitting layer.

2. The display device according to claim 1, wherein
the drive substrate includes a base material and a drive circuit layer laminated on the base material and including an interlayer insulating layer, and
the first interface and the second interface are provided at least on the interlayer insulating layer.

3. The display device according to claim 2, wherein
the first interface includes a first recess provided on the first main surface side of the interlayer insulating layer.

4. The display device according to claim 3, further comprising
a protective layer laminated on the second electrode, wherein
the first recess is filled with the protective layer.

5. The display device according to claim 4, wherein
the first recess is filled with the protective layer while a cavity is formed in the protective layer.

6. The display device according to claim 5, wherein
the first recess has a shape widening toward an inside of the interlayer insulating layer.

7. The display device according to claim 2, further comprising:
a protective layer laminated on the second electrode; and
a first recess provided on the first main surface side of the interlayer insulating layer, wherein
the first interface includes a boundary between the protective layer and the first recess.

8. The display device according to claim 7, wherein
the first recess has a shape widening toward the first main surface side.

9. The display device according to claim 1, wherein
the second interface includes a wiring structure provided in the interlayer insulating layer.

10. The display device according to claim 1, further comprising
the first interface and the second interface each provided in plural numbers.

11. The display device according to claim 1, wherein
the first interface includes an interface of a same type of material or different types of material.

12. The display device according to claim 1, wherein
the second interface includes an interface of a same type of material or different types of material.

13. The display device according to claim 1, wherein,
in the peripheral region, the first interface and the second interface have a frame shape.

14. The display device according to claim 1, wherein,
in the peripheral region, the first interface and the second interface have an uneven shape on an inside and an outside of the peripheral region.

15. The display device according to claim 1, wherein
the peripheral region is provided in a region near a scribe line.

16. An electronic apparatus comprising the display device according to claim 1.
